(19) United States
(12) Patent Application Publication
(10) Pub. No.: US 2026/0344270 A1
(43) Pub. Date: Oct. 29, 2026

(54) DISPLAY APPARATUS

(71) Applicant: LG Display Co., Ltd., Seoul (KR)

(72) Inventors: Manki Ji, Daegu (KR); Sungwoo Lee, Daegu (KR); Jinwoo Park, Daegu (KR); Kyeongseob Kwon, Muju-gun, Jeonbuk-do (KR)

(21) Appl. No.: 19/659,815

(22) Filed: Apr. 27, 2026

(30) Foreign Application Priority Data
Apr. 28, 2025 (KR) 10-2025-0055763

(51) Int. Cl. H10K 59/80; H10K 59/40; B60K 35/22

(52) U.S. Cl. CPC H10K 59/879; H10K 59/40; H10K 59/873; B60K 35/22; B60K 2360/1438; B60K 2360/1523

(57) ABSTRACT

A display apparatus includes a display area and a non-display area. A bezel area included in the non-display area includes a first area in which a plurality of first structures are disposed, wherein a first trench is disposed in the first area and penetrates through a touch insulating layer of the touch sensing unit.

### CROSS-REFERENCE TO RELATED APPLICATION

Pursuant to 35 U.S.C. § 119(a), this application claims the benefit of an earlier filing date and right of priority to Korean Patent Application No. 10-2025-0055763 filed on April 28, 2025, which is hereby incorporated by reference in its entirety.

### TECHNICAL FIELD

The present disclosure relates to a display apparatus.

### BACKGROUND

Display apparatuses are implemented in a variety of electronic devices in various fields. For example, a display apparatus can be used for displaying information inside a vehicle. A display apparatus disposed inside the vehicle may provide various types of information and images for a driver. In addition, the display apparatus may include a function of allowing the user to input information through a touch function of the display apparatus.

A display apparatus according to an example implementation of the present disclosure includes: a substrate including a display area and a non-display area disposed outside the display area; a bezel area located in the non-display area and including a first area in which a plurality of first structures are disposed; an encapsulation portion disposed on the plurality of first structures; a touch sensing unit disposed on the encapsulation portion and including a touch sensor and a touch insulating layer; and a first trench penetrating the touch insulating layer in the first area.

A display apparatus according to another example implementation of the present disclosure includes: a substrate including a display area and a non-display area disposed outside the display area; a bezel area located in the non-display area and including a first area in which a plurality of encapsulation dams are disposed; an organic insulating layer disposed over the plurality of encapsulation dams; a lens disposed on the organic insulating layer; one or more trenches penetrating the organic insulating layer in the first area; and a lens dam filling the one or more trenches.

The display apparatus according to an example implementation of the present disclosure may include a component for dividing the touch insulating layer made of an organic insulating material into two portions isolated from each other in the bezel area. Accordingly, the component may prevent the moisture from penetrating into the display area through the touch insulating layer, thereby improving the reliability of the product.

In addition, in the display apparatus according to an example implementation of the present disclosure, an exposed surface of the touch insulating layer in an area between the two portions isolated from each other may be covered with a passivation layer made of an inorganic insulating material, thereby achieving a structure robust to moisture permeation.

In the display apparatus according to an example implementation of the present disclosure, at least a portion of the lens dam overlaps at least a portion of the encapsulation dam in the vertical direction such that the height of the lens dam may be maintained. Accordingly, the flow of the insulating material having fluidity may be controlled to prevent the insulating material from flowing to the outer area of the display apparatus. As a result, the thickness uniformity of the lens protection member may be secured to reliably protect the lens.

In addition, according to an example implementation of the present disclosure, the lens dam may be formed in the same process as the process for forming the component for adjusting the viewing angle, such that the number of the process steps may be reduced. Accordingly, there is an effect that production energy required for production of the display apparatus may be reduced and greenhouse gas emission may be reduced.

The effects of the present disclosure are not limited to the effects as mentioned above, and other effects not mentioned will be clearly understood by those skilled in the art from the following descriptions.

It is to be understood that both the foregoing general description and the following detailed description of the present disclosure are examples and explanatory and are intended to provide further explanation of the disclosure as claimed.

### BRIEF DESCRIPTION OF DRAWINGS

FIG. 1 illustrates an example in which a display apparatus according to an example implementation of the present disclosure is applied to a vehicle.

FIG. 2 is a plan view of a display apparatus according to example implementations of the present disclosure.

FIG. 3 is an enlarged view of an area I of FIG. 2.

FIG. 4 is a cross-sectional view taken along a line II-II' of FIG. 3.

FIGS. 5 and 6 are diagrams illustrating examples of a lens.

FIGS. 7 and 8 are diagrams illustrating a display panel disposed inside a vehicle.

FIGS. 9 to 11 are diagrams illustrating a display apparatus according to an example implementation of the present disclosure.

FIGS. 12 to 14 are respectively diagrams illustrating display apparatuses according to some further implementation of the present disclosure.

FIGS. 15 and 16 are respectively diagrams illustrating display apparatuses according to some still further implementations of the present disclosure.

FIG. 17 is a diagram illustrating a display apparatus according to still another example implementation of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

As vehicles implement a greater number and variety of electronic devices, various display apparatuses can be disposed inside a vehicle and occupy an increasingly larger area within the vehicle. However, in some cases, the information, image, or video displayed on a screen of the display apparatus may be unrelated to the actual driving of the vehicle and may interfere with a driver of the vehicle. Accordingly, there is a need for a display apparatus for a vehicle that does not interfere with a driver's driving operations.

When information or images that are unrelated to driving are displayed on a display apparatus inside a vehicle, e.g., on a window in a frontward or upward direction of the driver's seat, this can hinder driving of the vehicle. Accordingly, in order reduce disturbances to the driver while driving the vehicle, a component for adjusting the viewing angle can be included in the display apparatus.

However, in such scenarios, the component for adjusting the viewing angle may be susceptible to moisture penetration. For example, moisture may penetrate into the display area through an organic insulating material. When the moisture penetrates into the display area, various problems may arise, such as corrosion of metal lines in the display apparatus.

For example, when a metal line such as a touch line for (touch functionality) is damaged in a display apparatus capable of sensing a user's touch input, a defect may occur during a touch operation, which may lead to a product defect.

Implementations of the present disclosure can provide a display apparatus that can help mitigate an organic insulating material from acting as a moisture flow path.

Implementations of the present disclosure can provide a display apparatus capable of improving the reliability of a product by preventing a touch line from being damaged due to moisture penetration.

Implementations of the present disclosure can provide a display apparatus capable of maintaining thickness uniformity of a protective member protecting a component for adjusting a viewing angle.

Implementations of the present disclosure can provide a display apparatus capable of reducing greenhouse gas emission by reducing production energy required for production of the display apparatus.

Purposes according to the present disclosure are not limited to the above-mentioned purpose. Other purposes and advantages according to the present disclosure that are not mentioned may be understood based on following descriptions, and may be more clearly understood based on implementations according to the present disclosure. Further, it will be easily understood that the purposes and advantages according to the present disclosure may be realized using means shown in the claims or combinations thereof.

Reference will now be made in detail to implementations of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and a method of achieving the advantages and features will become apparent with reference to example implementations described later in detail together with the accompanying drawings. However, the present disclosure is not limited to the implementations as disclosed under, but may be implemented in various different forms. Thus, these implementations are set forth only to make the present disclosure complete, and to completely inform the scope of the present disclosure to those of ordinary skill in the technical field to which the present disclosure belongs, and the present disclosure is only defined by the scope of the claims.

For simplicity and clarity of illustration, elements in the drawings are not necessarily drawn to scale. The same reference numbers in different drawings represent the same or similar elements, and as such perform similar functionality.

Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Examples of various implementations are illustrated and described further below. It will be understood that the description herein is not intended to limit the claims to the specific implementations described. On the contrary, it is intended to cover alternatives, modifications, and equivalents as may be included in the spirit and scope of the present disclosure as defined by the appended claims.

A shape (e.g., sizes, lengths, widths, heights, thicknesses, locations, radii, diameters, and areas), a ratio, an angle, a number, etc. disclosed in the drawings for describing implementations of the present disclosure are illustrative, and the present disclosure is not limited thereto.

The terminology used herein is directed to the purpose of describing particular implementations only and is not intended to be limiting of the present disclosure. As used herein, the singular constitutes "a" and "an" are intended to include the plural constitutes as well, unless the context clearly indicates otherwise. It will be further understood that the terms "comprise", "comprising", "include", and "including" when used in this specification, specify the presence of the stated features, integers, operations, elements, and/or components, but do not preclude the presence or addition of one or more other features, integers, operations, elements, components, and/or portions thereof.

Aspects are example aspects. “Implementations,” “examples,” “aspects,” and the like should not be construed as preferred or advantageous over other implementations. An implementation, an example, an example implementation, an aspect, or the like may refer to one or more implementations, one or more examples, one or more example implementations, one or more aspects, or the like, unless stated otherwise. Further, the term “may” encompasses all the meanings of the term “can.”

As used herein, the term "and/or" includes any and all combinations of one or more of associated listed items. Expression such as "at least one of" when preceding a list of elements may modify the entire list of elements and may not modify the individual elements of the list. In interpretation of numerical values, an error or tolerance therein may occur even when there is no explicit description thereof.

In addition, it will also be understood that when a positional relationship of two parts is described as being “on,” “above,” “below,” “next to,” or the like, unless “immediately” or “directly” is used, one or more other parts can be located between the two parts. For example, when a first element or layer is referred to as being present "on" a second element or layer, the first element may be disposed directly on the second element or may be disposed indirectly on the second element with a third element or layer being disposed between the first and second elements or layers.

It will be understood that when an element or layer is referred to as being "connected to", or "connected to" another element or layer, it may be directly on, connected to, or connected to the other element or layer, or one or more intervening elements or layers may be present.

In addition, it will also be understood that when an element or layer is referred to as being "between" two elements or layers, it may be the only element or layer between the two elements or layers, or one or more intervening elements or layers may also be present.

Further, as used herein, when a layer, film, region, plate, or the like is disposed "on" or "on top" of another layer, film, region, plate, or the like, the former may directly contact the latter or still another layer, film, region, plate, or the like may be disposed between the former and the latter. As used herein, when a layer, film, region, plate, or the like is directly disposed "on" or "on top" of another layer, film, region, plate, or the like, the former directly contacts the latter and still another layer, film, region, plate, or the like is not disposed between the former and the latter. Further, as used herein, when a layer, film, region, plate, or the like is disposed “under” another layer, film, region, plate, or the like, the former may directly contact the latter or still another layer, film, region, plate, or the like may be disposed between the former and the latter. As used herein, when a layer, film, region, plate, or the like is directly disposed "under" another layer, film, region, plate, or the like, the former directly contacts the latter and still another layer, film, region, plate, or the like is not disposed between the former and the latter.

In descriptions of temporal relationships, for example, temporal precedent relationships between two events such as “after”, “subsequent to”, “before”, etc., another event may occur therebetween unless “directly after”, “directly subsequent” or “directly before” is not indicated.

When a certain implementation may be implemented differently, a function or an operation specified in a specific block may occur in a different order from an order specified in a flowchart. For example, two blocks in succession may be actually performed substantially concurrently, or the two blocks may be performed in a reverse order depending on a function or operation involved.

It will be understood that, although the terms "first", "second", "third", A, B, (a), (b), and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described under could be termed a second element, component, region, layer or section, without departing from the spirit and scope of the present disclosure.

The features of the various implementations of the present disclosure may be partially or entirely combined with each other, and may be technically associated with each other or operate with each other. The implementations may be implemented independently of each other and may be implemented together in an association relationship with each other.

In interpreting a numerical value, the value is interpreted as including an error range unless there is no separate explicit description thereof.

In description of flow of a signal, for example, when a signal is delivered from a node A to a node B, this may include a case where the signal is transferred from the node A to the node B via another node unless a phrase 'immediately transferred' or 'directly transferred' is used.

Hereinafter, a display apparatus according to each implementation of the present disclosure will be described with reference to the accompanying drawings.

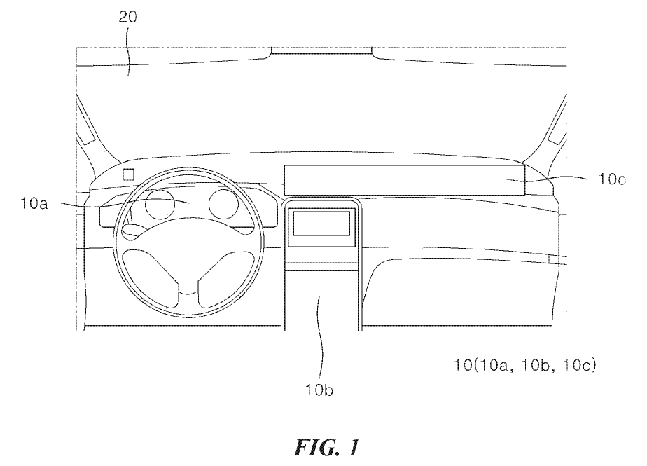

FIG. 1 illustrates an example in which a display apparatus according to an example implementation of the present disclosure is applied to a vehicle.

Referring to FIG. 1, a display apparatus including a display panel 10 according to implementations of the present disclosure may be disposed inside a vehicle. For example, the display panel 10 may include a first display area 10a, a second display area 10b, and a third display area 10c. In an example, the first display area 10a may be disposed in front of the driver's seat, the third display area 10c may be disposed in front of the passenger seat, and the second display area 10b may be disposed in a common space between the driver's seat and the passenger seat.

The first display area 10a may provide information on the instrument panel indicating the driving state to the user of the driver's seat. The second display area 10b or the third display area 10c may display navigation or video according to a user's selection or a driving state of the vehicle. In an example, when the vehicle is running, the viewing angle of the second display area 10band/or the third display area 10c may be controlled so as not to interfere with the driver's driving. For example, the viewing angle may be controlled so that an image provided from the second display area 10b and/or the third display area 10c is not reflected on the glass window in the frontward and upward direction of the driver’s seat so as not to interfere with the driver's driving.

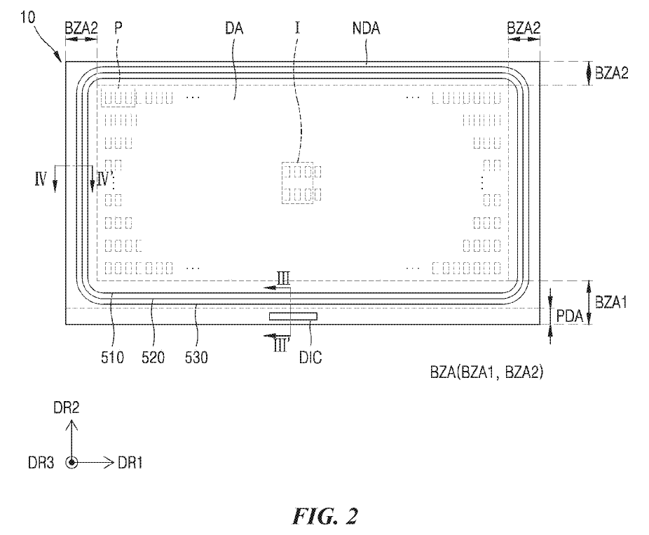

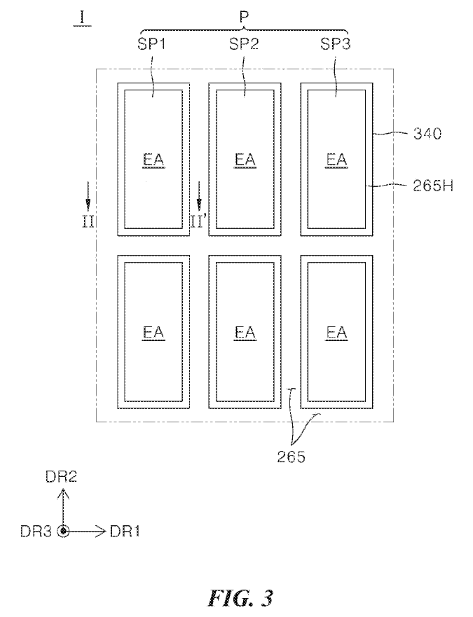

FIG. 2 is a plan view of a display apparatus according to implementations of the present disclosure. FIG. 3 is an enlarged view of an area I of FIG. 2. FIG. 3 illustrates only a bank 265, a bank hole 265H, and a lens 340 for convenience of illustration.

Referring to FIGS. 2 and 3, the display apparatus according to an example implementation of the present disclosure may include a display panel 10 including a display area DA and a non-display area NDA positioned outside the display area DA. The non-display area NDA may be also referred to as an edge area or a bezel area.

The display panel 10 may include the display area DA and the non-display area NDA. The display area DA may be an area in which an image is displayed. The non-display area NDA may be an area in which no image is displayed. The non-display area NDA may be positioned in the peripheral area (or edge area) of the display panel 10. However, implementations of the present disclosure are not limited thereto. For example, a remaining area except for a light emission area in which light is emitted to the outside in the display area DA may be referred to as the non-display area NDA. A bezel area BZA of the display apparatus may be defined by the non-display area NDA. The bezel area BZA may surround the outside of the display area DA. The bezel area BZA may include a first bezel area BZA1 and a second bezel area BZA2. For example, the first bezel area BZA1 may be positioned in one side of the display panel 10, and the second bezel area BZA2 may be positioned in three sides of the display panel 10, but is not limited thereto. For example, the first bezel area BZA1 may be positioned at lower portion of the display panel 10, and the second bezel area BZA 2 may be positioned at an upper portion, a left portion, and a right portion of the display panel 10. The lower portion of the display panel 10 in which the first bezel area BZA1 is disposed may be an area in which a pad area PDA in which a plurality of pads electrically connected to a printed circuit board or a driving circuit chip are disposed is disposed.

A plurality of pixels P may be disposed in the display area DA. Each of the plurality of pixels P may include a plurality of sub-pixels. For example, each of the plurality of pixels P may include a plurality of sub-pixels SP1, SP2, and SP3, but is not limited thereto. More or less sub-pixels may be included. An image may be displayed through the plurality of sub-pixels SP1, SP2, and SP3 in the display area DA. The plurality of sub-pixels SP1, SP2, and SP3 may be arranged in an array in the display area DA. In an example, the plurality of sub-pixels SP1, SP2, and SP3 may be spaced apart from each other in the first direction DR1 and the second direction DR2 intersecting the first direction DR1 of the display area DA to form a matrix arrangement. In an example, the plurality of sub-pixels SP1, SP2, and SP3 of one pixel P may be spaced apart from each other in the first direction DR1. In an example, the plurality of sub-pixels SP1, SP2, and SP3 of one pixel P and the plurality of sub-pixels SP1, SP2, and SP3 of another pixel P may be spaced apart from each other in the second direction DR2. The first direction DR1 may be a longitudinal direction, a X-axis direction, or a row direction, and the second direction DR2 may be a transverse direction, a Y-axis direction, or a column direction. However, implementation of the present disclosure are not limited thereto, and the arrangement shape, arrangement order, and arrangement direction of the sub-pixels SP1, SP2, and SP3 may be variously changed.

In the present disclosure, one pixel P is configured to include a plurality of sub-pixels, such as the first sub-pixel SP1, the second sub-pixel SP2, and the third sub-pixel SP3. However, implementations of the present disclosure are not limited thereto. For example, one pixel P may further include an additional sub-pixel.

The sub-pixels SP1, SP2, and SP3 may be implemented to emit light of the same color, such as white light, or may be implemented to respectively emit light of different colors, such as red, green, and blue colors. In another example implementation, each sub-pixel may display one color among cyan, magenta and yellow. In various implementations, each sub-pixel may display one color among red, green, blue and white. For example, the first sub-pixel SP1 may emit the red light, the second sub-pixel SP2 may emit the green light, and the third sub-pixel SP3 may emit the blue light. However, implementations of the present disclosure are not limited thereto.

Various lines and circuits for driving the plurality of subpixels SP1, SP2, and SP3 of the display area DA may be disposed in the non-display area NDA. For example, driving circuits including a gate driving circuit and a data driving circuit may be disposed in the non-display area NDA. Several drivers for driving the display area DA may be disposed in the non-display area NDA. For example, the driver may include a gate driver and a data driver. However, implementations of the present disclosure are not limited thereto. A pad area PDA may be included in one edge of the non-display area NDA. For example, the pad area PDA may be included in the lower portion of the display panel 10. However, implementations of the present disclosure are not limited thereto.

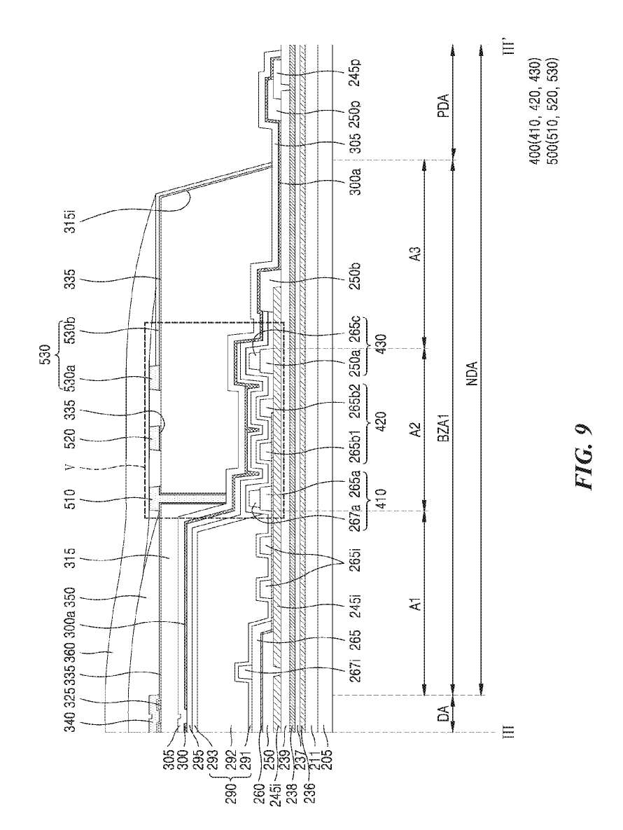

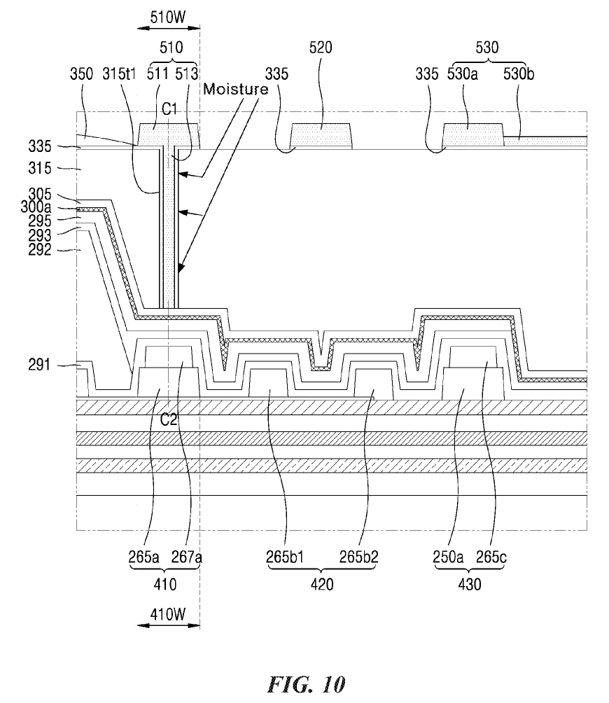

A plurality of lens dams 510, 520, and 530 may be disposed in the non-display area NDA so as to be spaced apart from each other. The plurality of lens dams 510, 520, and 530 may include a first lens dam 510, a second lens dam 520, and a third lens dam 530. Each of the lens dams 510, 520, and 530 may extend along the shape of the display area DA so as to surround the outside of the display area DA. For example, the plurality of lens dams 510, 520, and 530 may be disposed to extend along the shape of the display area DA in the non-display area NDA. Each of the lens dams 510, 520, and 530 may have a continuous line shape. For example, each of the lens dams 510, 520, and 530 may have a closed-loop line shape. This will be described later with reference to FIGS. 9 and 10. For example, the second lens dam 520 may be disposed outwardly of the first lens dam 510, and the third lens dam 530 may be disposed outwardly of the second lens dam 520, but is not limited thereto.

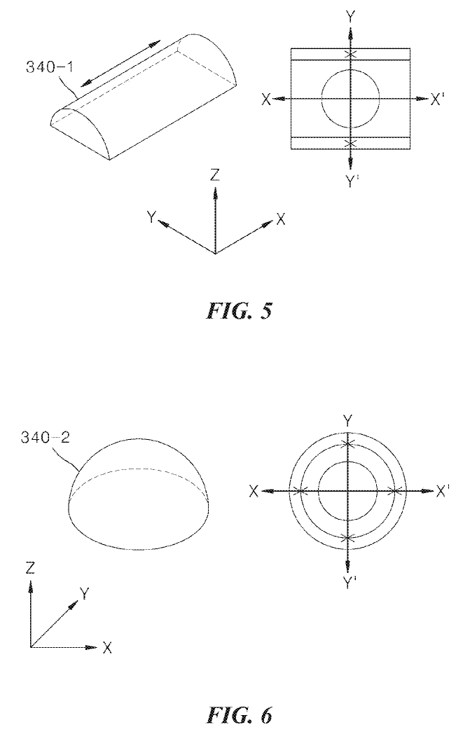

Referring to FIG. 3, the sub-pixels SP1, SP2, and SP3 may be distinguished from each other by a bank 265. For example, the bank hole 265H as an open area of the bank 265 may constitute a boundary area between neighboring sub-pixels and may define the light-emission area EA. An area not covered with the bank 265 in each of the sub-pixels SP1, SP2, and SP3 may be the light-emission area EA. The lens 340 as the viewing angle adjusting member may be disposed in each of the sub-pixels SP1, SP2, and SP3 and may overlap the light-emission area EA. The lens 340 may include a hemispherical lens. However, implementations of the present disclosure are not limited thereto. For example, the lens 340 may include a cylindrical lens. In an example, the lens 340 may function to prevent an unnecessary screen from being visible to the user. The lens 340 may be referred to as a component for adjusting a viewing angle. This will be described later with reference to FIGS. 5 and 6.

Hereinafter, an example implementation of one sub-pixel will be described.

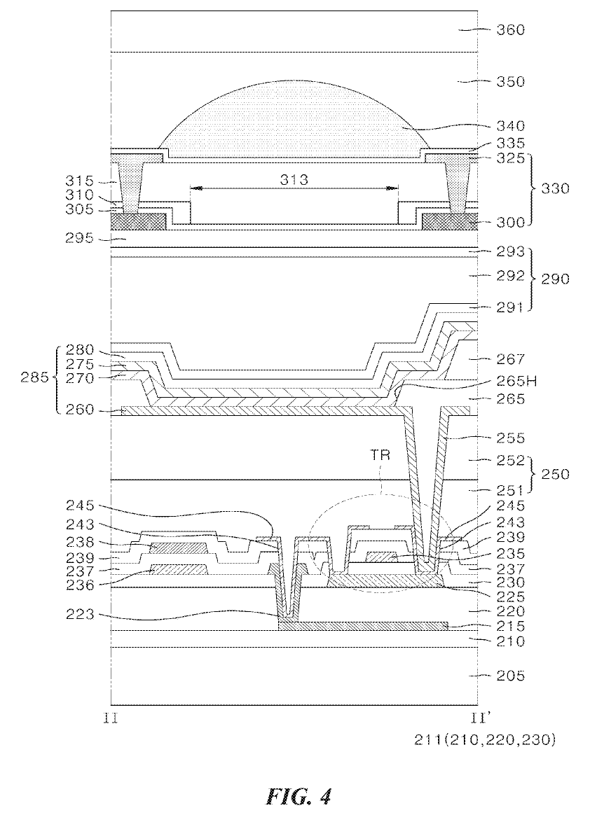

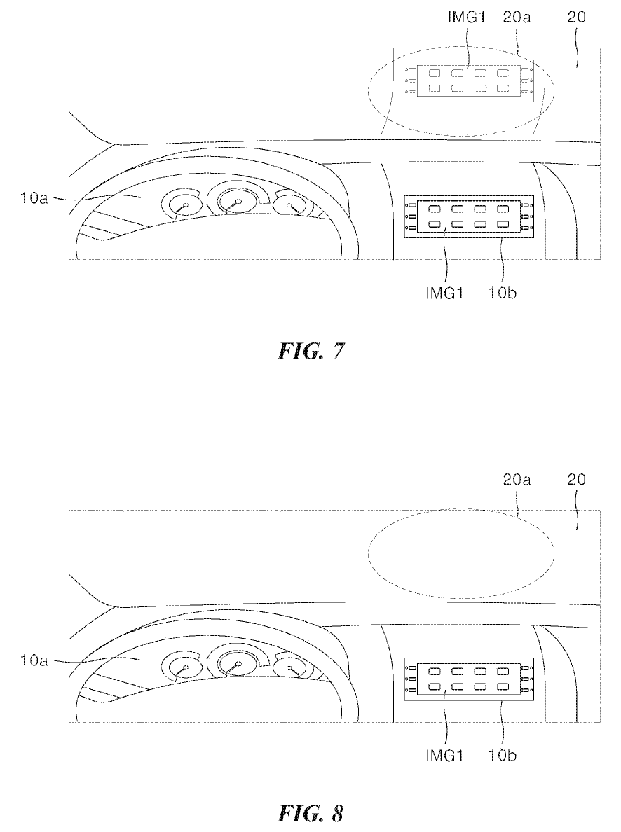

FIG. 4 is a cross-sectional view of one sub-pixel taken along a line II-II' of FIG. 3. FIGS. 5 and 6 are diagrams illustrating the lens. FIGS. 7 and 8 are diagrams illustrating a display panel disposed inside a vehicle.

Referring to FIG. 4, the display panel 10 (see FIG. 2) may include a substrate 205, a pixel driving circuit including a transistor TR, a light-emitting element 285, a touch sensing unit, the lens 340, a lens protection layer 350, and a polarizing layer 360.

One sub-pixel may include the light-emitting element 285 and a pixel driving circuit for applying a driving current to the light-emitting element 285. The pixel driving circuit may be disposed on the substrate 205, and the light-emitting element 285 may be disposed on the pixel driving circuit. The pixel driving circuit may include a driving transistor, one or more switching transistors, and a capacitor, but is not limited thereto. In an example, the transistor TR may be a driving transistor. However, implementations of the present disclosure are not limited thereto.

The substrate 205 may include a glass or flexible plastic film. When the substrate 205 is a flexible plastic film, the substrate 205 may include multiple layers made of insulating materials. A first buffer layer 210 may be disposed on the substrate 205. The first buffer layer 210 may cover a surface of the substrate 205. For example, the first buffer layer 210 may entirely cover the surface of the substrate 205. The first buffer layer 210 may reduce or prevent penetration of moisture, oxygen, or impurities through the substrate 205. The first buffer layer 210 may be implemented as a single layer or a multilayer made of an inorganic insulating material such as silicon oxide (SiOx) or silicon nitride (SiNx).

A light shielding layer 215 may be disposed on the first buffer layer 210. The light shielding layer 215 may be disposed to overlap with the transistor TR in the vertical direction. The light shielding layer 215 may prevent external light from being incident on the transistor TR. To this end, an opaque metal material may be included in the light shielding layer 215. A second buffer layer 220 may be disposed on the light shielding layer 215. The second buffer layer 220 may be disposed across the entire surface of the substrate 205. For example, the second buffer layer 220 may be disposed on the light shielding layer 215 and the surface of the first buffer layer 210 exposed by the light shielding layer 215. The second buffer layer 220 may protect the transistor TR from moisture, oxygen, or impurities. The second buffer layer 220 may be implemented as a single layer or a multilayer made of an inorganic insulating material such as silicon oxide (SiOx) or silicon nitride (SiNx). However, implementations of the present disclosure are not limited thereto.

The transistor TR may be disposed on the second buffer layer 220. The transistor TR may include a semiconductor layer 225, a gate electrode 235, and source/drain electrodes 245. The semiconductor layer 225 may include a channel area and a source/drain area. The area of the semiconductor layer 225 disposed to overlap the gate electrode 235 in the vertical direction may be a channel area. The source/drain areas may be disposed on both opposing sides of the channel area CH, respectively. The semiconductor layer 225 may be implemented as one of an oxide semiconductor layer, a polysilicon semiconductor layer, and a low-temperature polysilicon semiconductor layer, or a combination thereof. The semiconductor layer 225 may be disposed to overlap the light shielding layer 215 in the vertical direction. The light shielding layer 215 may prevent the external light from being incident on the semiconductor layer 225.

A gate insulating layer 230 may be disposed between the semiconductor layer 225 and the gate electrode 235. The gate insulating layer 230 is an insulating layer for insulating the semiconductor layer 225 and the gate electrode 235 from each other. The gate insulating layer 230 may cover the semiconductor layer 225. The gate insulating layer 230 may be implemented as a single layer or a plurality of layers made of silicon oxide (SiOx) or silicon nitride (SiNx). The gate insulating layer 230 may extend into the non-display area NDA. A combination of the first buffer layer 210, the second buffer layer 220, and the gate insulating layer 230 extending into the non-display area NDA may be referred to as a first insulating structure 211.

The gate electrode 235 may be disposed on the gate insulating layer 230. The gate electrode 235 may be implemented as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the material thereof is not limited thereto.

The first intermediate electrode layer 236 may be disposed on the gate insulating layer 230. The first intermediate electrode layer 236 may be disposed in a different area from the area where the gate electrode 235 is disposed. The first intermediate electrode layer 236 may be made of the same material as that of the gate electrode 235 and be formed in the same process as the process of forming the gate electrode 235, but is not limited thereto. The first intermediate electrode layer 236 may act as one of signal lines for transmitting various signals. In an example, the first intermediate electrode layer 236 may extend from the display area DA through the bezel area BZA1 and BZA2 to the pad area PDA. For example, an area where the first intermediate electrode layer 236 is disposed may be an area where the driving circuit chip DIC (see FIG. 2) is disposed.

The first intermediate electrode layer 236 may be implemented as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, the material thereof is not limited thereto.

A via hole extending through the gate insulating layer 230 and the second buffer layer 220 may be disposed. The via hole may expose a portion of the surface of the light shielding layer 215. A via electrode 223 may be disposed in the via hole. The via electrode 223 may contact and be connected to the portion of the surface of the light shielding layer 215 exposed through the via hole. The via electrode 223 may extend from the inside of the via hole to a portion of an upper surface of the gate insulating layer 230.

A first interlayer insulating layer 237 may be disposed on the gate electrode 235 and the first intermediate electrode layer 236. For example, the first interlayer insulating layer 237 may be disposed on the gate electrode 235 and the first intermediate electrode layer 236 and the portion of the gate insulating layer 230 exposed by the gate electrode 235 and the first intermediate electrode layer 236, but is not limited thereto. The first interlayer insulating layer 237 may be implemented as a single layer or multiple layers made of an inorganic insulating material such as silicon oxide (SiOx) or silicon nitride (SiNx) , but is not limited thereto.

A second intermediate electrode layer 238 may be disposed on the first interlayer insulating layer 237. The second intermediate electrode layer 238 may be disposed in a different area from an area in which the transistor TR is disposed. For example, the second intermediate electrode layer 238 may be disposed to overlap the first intermediate electrode layer 236 in the vertical direction with the first interlayer insulating layer 237 interposed therebetween.

The second intermediate electrode layer 238 may include a metal material. The second intermediate electrode layer 238 may be made of the same material as that of the first intermediate electrode layer 236, but is not limited thereto. For example, the second intermediate electrode layer 238 may be implemented as a single layer or multiple layers made of any one of molybdenum (Mo), aluminum (Al), chromium (Cr), gold (Au), titanium (Ti), nickel (Ni), neodymium (Nd), and copper (Cu), or an alloy thereof. However, implementations of the present disclosure are not limited thereto. In an example, the second intermediate electrode layer 238 may act as a plurality of lines that transmit various signals from the driving circuit chip DIC (see FIG. 2) or the driver disposed on the printed circuit board to the display area DA. For example, the various signals may include a high potential voltage, a low potential voltage, a scan signal, a data signal, a touch driving signal, or the like. However, implementations of the present disclosure are not limited thereto. In an example, the second intermediate electrode layer 238 may extend from the display area DA through the bezel area BZA1 and BZA2 to the pad area PDA. For example, the area where the second intermediate electrode layer 238 is disposed may be an area where the driving circuit chip DIC (see FIG. 2) is disposed.

A second interlayer insulating layer 239 may be disposed on the second intermediate electrode layer 238 and the first interlayer insulating layer 237. The second interlayer insulating layer 239 may have a plurality of contact holes 243 formed therein. The plurality of contact holes 243 may extend through the second interlayer insulating layer 239, the first interlayer insulating layer 237, and the gate insulating layer 230 so as to contact portions of surfaces of the source/drain areas of the semiconductor layer 225, respectively. A portion of the contact hole 243 may be disposed to overlap the via electrode 223 in the vertical direction. The second interlayer insulating layer 239 may be made of the same material as that of the first interlayer insulating layer 237, but is not limited thereto. The second interlayer insulating layer 239 may be implemented as a single layer or multiple layers made of an inorganic insulating material such as silicon oxide (SiOx) or silicon nitride (SiNx), but is not limited thereto.

The source/drain electrodes 245 may be disposed on the second interlayer insulating layer 239. The source/drain electrodes 245 may be disposed in the contact holes 243. The source/drain electrodes 245 may extend through the second interlayer insulating layer 239, the first interlayer insulating layer 237, and the gate insulating layer 230 to be connected to the source/drain areas of the semiconductor layer 225, respectively. One of the source/drain electrodes 245 may be connected to the via electrode 223 and thus be connected to the light shielding layer 215. Each of the source/drain electrodes 245 may be implemented as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. However, implementations of the present disclosure are not limited thereto. In an example, each of the source/drain electrodes 245 may have a stacked structure of a titanium layer/aluminum layer/titanium layer (Ti/Al/Ti).

A planarization layer 250 may be disposed on the source/drain electrode 245 and the second interlayer insulating layer 239. The planarization layer 250 may planarize a step due to the pixel driving circuit thereunder. The planarization layer 250 may be formed in a structure in which a plurality of planarization layers are stacked in the vertical direction. For example, in the drawing, the planarization layer 250 has a structure in which a first planarization layer 251 and a second planarization layer 252 are stacked in the vertical direction. The first planarization layer 251 may be disposed on the source/drain electrode 245 and the second interlayer insulating layer 239, and the second planarization layer 252 may be disposed on the first planarization layer 251. However, implementation of the present disclosure are not limited thereto. For example, a multilayer structure in which a third planarization layer (not shown) is further stacked on the second planarization layer 252 may be included in implementations of the present disclosure. However, implementations of the present disclosure are not limited thereto. For example, the planarization layer 250 may be formed in a single layer. For example, the planarization layer 250 may include an organic insulating material such as polyimide or acrylic resin.

The first planarization layer 251 and the second planarization layer 252 may be formed of one or more materials of acrylic resin, epoxy resin, phenolic resin, polyamides resin, unsaturated polyesters resin, polyphenylene resin, polyphenylene sulfides resin, and benzocyclobutene, but implementations are not limited thereto.

The light-emitting element 285 may be formed on the planarization layer 250. For example, the light-emitting element 285 may be disposed on the second planarization layer 252. The light-emitting element 285 may include a first electrode 260, a light-emitting layer 270, a second electrode 275, and a capping layer 280, but implementations are not limited thereto.

The light-emitting element 285 may be electrically connected to the pixel driving circuit via the first electrode 260. For example, a pixel contact hole 255 may be formed in the planarization layer 250. The a pixel contact hole 255 may passing through the planarization layer 250, the second interlayer insulating layer 239, the first interlayer insulating layer 237, and the gate insulating layer 230. The pixel contact hole 255 may expose a portion of a surface of the other of the source/drain electrodes 245.

The first electrode 260 of the light-emitting element 285 may be electrically connected to the other of the source/drain electrodes 245 via the pixel contact hole 255. The first electrode 260 may be disposed on and contact the pixel contact hole 255 so as to be connected to the other of the source/drain electrodes 245 via the pixel contact. The light-emitting layer 270, the second electrode 275, and the capping layer 280 are stacked in the vertical direction.

The first electrode 260 may include a transparent conductive layer. The first electrode 260 may include ITO (Indium Tin Oxide) or IZO (Indium Zinc Oxide). Alternatively, the first electrode 260 may have a single-layer or multi-layer structure including a reflective metal film made of one of silver (Ag), aluminum (Al), gold (Au), nickel (Ni), and chromium (Cr) or an alloy thereof. The first electrode 260 may also be referred to as an anode electrode or a pixel electrode.

The bank 265 may be disposed on the first electrode 260. The bank 265 may be disposed to cover an edge of the first electrode 260. A portion of the bank 265 may extend onto the planarization layer 250. In an example, the bank 265 may fill a remaining portion of the trench other than the portion thereof filled with the pixel contact hole 255. The bank 265 may have the bank hole 265H defined therein as an opening exposing a portion of the upper surface of the first electrode 260. The portion of the upper surface of the first electrode 260 not covered with the bank 265 and exposed through the bank hole may be the light-emission area EA. The bank 265 may be made of an organic insulating material. The bank 265 may include, for example, photosensitive polyimide, photoacryl, or benzocyclobutene (BCB). In an example, the bank 265 may include a black material, a light blocking material, or a light absorbing material. The bank 265 may include a material that absorbs light in a specific wavelength range. The bank 265 may have a structure in which at least two color filters of different colors among a red color filter, a green color filter, and a blue color filter are stacked.

The light-emitting layer 270 may be disposed on the first electrode 260. For example, the light-emitting layer 270 may be disposed on the first electrode 260 and the bank 265. The light-emitting layer 270 may include a hole transport layer (HTL), an organic light-emitting layer (EML), an electron transport layer (ETL), a hole blocking layer (HBL), a hole injection layer (HIL), an electron blocking layer (EBL), and an electron injection layer (EIL). The light-emitting layer 270 may have a multi-stack structure in which two or more organic emission layers (EML) are stacked.

The second electrode 275 may be disposed on the light-emitting layer 270. The second electrode 275 may be formed over the entire surface of the substrate 205 so as to be commonly connected to the light-emitting layers 270 formed in all sub-pixels. Accordingly, the second electrode 275 may also be referred to as a cathode electrode or a common electrode. The second electrode 275 may include a transflective conductive material. For example, the second electrode 275 may include a metal material such as magnesium (Mg), silver (Ag), or an alloy (Ag-Mg) of silver (Ag) and magnesium (Mg). In an example, the second electrode 275 may include a transparent conductive layer made of, for example, indium-tin-oxide (ITO) or indium-zinc-oxide (IZO).

The capping layer 280 may be disposed on the second electrode 275. The capping layer 280 may correct optical characteristics by preventing light generated from the light-emitting layer 270 from being lost.

An encapsulation portion 290 may be disposed on the light-emitting element 285. For example, the encapsulation portion 290 may be disposed on the capping layer 280. The encapsulation portion 290 may protect the light-emitting element 285 from external oxygen or moisture. The encapsulation portion 290 may extend into the non-display area NDA while covering the display area DA.

The encapsulation portion 290 may include a single layer or a multilayer structure in which a plurality of encapsulation layers are stacked. The encapsulation portion 290 may include a multilayer structure in which a first encapsulation layer 291, a second encapsulation layer 292, and a third encapsulation layer 293 are stacked, but implementations are not limited thereto. The second encapsulation layer 292 may be disposed between the first encapsulation layer 291 and the third encapsulation layer 293. More or less encapsulation layer may be included.

The first encapsulation layer 291 may be disposed on the light-emitting element 285. The first encapsulation layer 291 may be disposed on the capping layer 280. The second encapsulation layer 292 may be disposed on the first encapsulation layer 291. The second encapsulation layer 292 may cover the first encapsulation layer 291 and may have a sufficient thickness so as to have a flat upper surface. The second encapsulation layer 292 may prevent foreign substances from invading into the light-emitting element 285. The third encapsulation layer 293 may be disposed on the second encapsulation layer 292.

An inorganic insulating material may be included in each of the first encapsulation layer 291 and the third encapsulation layer 293. For example, each of the first encapsulation layer 291 and the third encapsulation layer 293 may include at least one of silicon nitride (SiNx), silicon oxide (SiOx), and silicon oxynitride (SiON). An organic insulating material may be included in the second encapsulation layer 292. For example, the second encapsulation layer 292 may include at least one of epoxy, polyimide, polyethylene, and acrylate.

A touch sensing unit may be disposed on the encapsulation portion 290 and include a touch sensor and a touch insulating layer. A plurality of lenses 340 may be disposed on the touch sensing unit. The touch sensing unit may include a first touch buffer layer 295, a touch sensor 330, a second touch buffer layer 305, a light blocking pattern 310, a touch insulating layer 315, and a passivation layer 335, but is not limited thereto.

The first touch buffer layer 295 may be disposed on the third encapsulation layer 293. The first touch buffer layer 295 may include an inorganic insulating material. For example, the first touch buffer layer 295 may include silicon nitride (SiNx). The first touch buffer layer 295 may relieve stress between the encapsulation portion 290 and the touch sensor 330.

The touch sensor 330 may include a plurality of touch electrodes 325 and a plurality of bridge electrodes 300. For example, the touch sensor 330 may be disposed on the first touch buffer layer 295. The plurality of touch electrodes 325 and the plurality of bridge electrodes 300 may be disposed in different layers. For example, the plurality of bridge electrodes 300 may be disposed on the first touch buffer layer 295. The plurality of touch electrodes 325 may be disposed on the touch insulating layer 315.

The touch sensor 330 may further include a plurality of touch lines for electrically connecting the plurality of touch electrodes 325 to the touch driving circuit. The touch sensor 330 may be implemented in the form of a touch panel outside of the display panel 10 or be integrated inside of the display panel 10. The touch driving circuit can supply a touch driving signal to at least one of a plurality of touch electrodes 325, and sense at least one of the plurality of touch electrodes 325 to generate touch sensing data.

The touch sensing circuit can perform touch sensing. For example, the touch sensing circuit can perform touch sensing by a self-capacitance sensing technique or a mutual-capacitance sensing technique, without being limited thereto.

In the example where the touch sensing circuit performs touch sensing by the self-capacitance sensing technique, the touch sensing circuit can perform touch sensing based on capacitance between each touch electrode and a touch object (e.g., a finger, a pen, and the like).

In the example where the touch sensing circuit performs touch sensing by the mutual-capacitance sensing technique, the touch sensing circuit can perform touch sensing based on a capacitance between touch electrodes.

Each of the plurality of touch electrodes 325 or the plurality of bridge electrodes 300 may be implemented as a single layer or multiple layers made of any one of molybdenum (Mo), aluminum (Al), chromium (Cr), gold (Au), titanium (Ti), nickel (Ni), neodymium (Nd), and copper (Cu) or an alloy thereof. For example, each of the plurality of touch electrodes 325 or the plurality of bridge electrodes 300 may be a stacked structure of titanium layer/aluminum layer/titanium layer (Ti/Al/Ti), but is not limited thereto.

The second touch buffer layer 305 may be disposed on the plurality of bridge electrodes 300 and the first touch buffer layer 295. The touch insulating layer 315 may be disposed between adjacent ones of the plurality of touch electrodes 325 and between adjacent ones of the plurality of bridge electrodes 300. The light blocking pattern 310 may be disposed on the second touch buffer layer 305. The plurality of touch electrodes 325 may be disposed on the touch insulating layer 315 so as to be spaced apart from each other. The bridge electrode 300 may electrically connect adjacent touch electrodes 325 to each other. To this end, each touch electrode 325 may extend through the touch insulating layer 315, the light blocking pattern 310, and the second touch buffer layer 305 so as to be electrically connected to the bridge electrode 300. Adjacent touch electrodes 325 may be electrically insulated from each other by the passivation layer 335.

An inorganic insulating material may be included in the second touch buffer layer 305 or the passivation layer 335. For example, the second touch buffer layer 305 or the passivation layer 335 may be made of an inorganic insulating material including silicon nitride (SiNx).

The touch insulating layer 315 may spread or condense the light generated from the light-emitting element 285 such that the spread or condensed light is directed to the lens 340. To this end, the touch insulating layer 315 may be formed to have a sufficient thickness. It may be difficult to implement the inorganic insulating material layer as the touch insulating layer 315 so as to have a thickness required by the touch insulating layer 315. Accordingly, the touch insulating layer 315 may include an organic insulating material. For example, the touch insulating layer 315 may include an organic insulating material such as acryl resin, epoxy resin, phenolic resin, polyamide resin, or polyimide resin. However, the material thereof is not limited thereto.

The light blocking pattern 310 may be disposed on the second touch buffer layer 305. The light blocking pattern 310 may prevent color mixing between light beams from adjacent light-emitting elements 285 from occurring. In addition, the light blocking pattern 310 may block light from the outside or may block light reflected from the outside. Accordingly, the luminance of the display apparatus may be further improved.

To this end, an opaque material may be included in the light blocking pattern 310. For example, the light blocking pattern 310 may include an organic insulating material including a black pigment or a black dye. In an example, the organic insulating material may include an organic material such as a benzocyclobutene resin, an epoxy resin, a polyimide resin, an acrylic resin, or a photosensitive polymer. However, implementations of the present disclosure are not limited thereto.

A plurality of opening areas 313 may be disposed in the light blocking pattern 310. In an example, at least a portion of the opening area 313 may be disposed to overlap the light-emitting area EA of the light-emitting element 285. In an example implementation, one opening area 313 defined in the light blocking pattern 310 may overlap the light-emission area EA of one sub-pixel SP. However, implementations of the present disclosure are not limited thereto.

The plurality of lenses 340 may be disposed on the passivation layer 335. Adjacent lenses 340 may be arranged to be spaced apart from each other by a predetermined spacing. In an example, one lens 340 may be disposed to overlap one opening area 313 defined in the light blocking pattern 310, but is not limited thereto.

The lens 340 may include an organic insulating material. For example, the lens 340 may include an organic insulating material having a second density that is relatively higher than a first density of the touch insulating layer 315. The organic insulating material having the second density relatively higher than the first density of the touch insulating layer 315 may prevent the moisture from penetrating therethrough.

The lens 340 may be a hemispherical lens overlapping the opening area 313 in the vertical direction. For example, the lens 340 may have a hemispherical shape in which a convex surface protrudes toward the lens protection layer 350. For example, the convex surface of the lens 340 may be in contact with the lens protection layer 350. A light-receiving surface of the lens 340 facing the protruding convex surface of the lens 340 and receiving the light generated from the light-emitting element 285 may be a flat surface. The light-receiving surface of the lens 340 may be in contact with the passivation layer 335.

The light generated from the light-emitting element 285 and passing through the opening area 313 may be provided to the light-receiving surface of the lens 340 and refracted by the convex surface of the lens 340 to be emitted to the outside. The light beams emitted in various directions from the light-emitting element 285 may be subjected to the change in the travel path by the lens 340 so as to be condensed in the frontward direction. Accordingly, the viewing angle of the display apparatus may be controlled.

As shown in FIGS. 5 and 6, the lens 340 may include at least one of a first lens 340-1 or a second lens 340-2. The first lens 340-1 and the second lens 340-2 may have different shapes.

For example, referring to FIG. 5, the first lens 340-1 may have a rectangular bottom surface and may have a hemispherical cylindrical shape having a hemispherical side surface in a cross-sectional view. In the bottom surface of the rectangle of the first lens 340-1, light travel of the light emitted from a width area of one sub-pixel may not be limited in a first direction X-X' (or row direction), while light travel of the light emitted from a width area of one sub-pixel may be limited in a second direction Y-Y' (or column direction) as indicated by a mark “ⅹ”. Accordingly, the light traveling in the vertical direction may be limited, thereby controlling the viewing angle in the vertical direction.

In addition, referring to FIG. 6, the second lens 340-2 may have a circular bottom surface and may have a hemispherical shape. Thus, in the circular bottom surface of the second lens 340-2, light travel of the light emitted from a width area of one sub-pixel may be limited in a first direction X-X' (or row direction) as indicated by a mark “ⅹ”, while light travel of the light emitted from a width area of one sub-pixel may be limited in a second direction Y-Y' (or column direction) as indicated by a mark “ⅹ”. When the display apparatus is disposed in the vehicle, the light travel along each of the vertical and horizonal directions may be limited such that the viewing angle in each of the vertical and horizontal directions of the display apparatus may be limited. Accordingly, when the second lens 340-2 is used in the display apparatus in front of the driver's seat, the image therefrom can be individually recognized only by the driver on the driver's seat. Further, when the second lens 340-2 is used in the display apparatus in front of the passenger's seat, the image therefrom can be individually recognized only by the passenger on the passenger's seat.

Referring to FIGS. 7 and 8, one or more display areas 10a and 10b may be disposed in the vehicle. The at least one display area 10a and 10b may include the first display area 10a and the second display area 10b. In addition, although not shown in the drawings, the third display area 10c (see FIG. 1) disposed in front of the passenger seat may be disposed.

Referring to FIG. 7, the viewing angle adjustment component may not be disposed in the display panel disposed in the second display area 10b positioned between the first display area 10a and the third display area 10c among the display areas 10a to 10c. Then, an image or an image IMG1 provided from the second display area 10b may reflect onto a first position 20a of the front glass 20 in the frontward and upward direction of the second display area 10b. The image IMG1 reflecting onto the first position 20a may interfere with the field of view of the user (or the driver). In this regard, as shown in FIG. 8, when the viewing angle adjustment component such as the lens as shown in FIG. 5 and FIG. 6 is disposed in the display panel disposed in the second display area 10b, the light travel along the vertical and/or horizontal direction may be limited such that the viewing angle along the vertical and/or horizontal direction of the display panel disposed in the second display area 10b may be limited. Thus, the image IMG1 may not reflect onto the first position 20a. Accordingly, the field of view of the driver may be prevented from being interfered therewith when the driver is driving the vehicle.

The lens protection layer 350 may be disposed on the lens 340. The polarization layer 360 may be disposed on the lens protection layer 350. The lens protective layer 350 may protect the lens 340 disposed thereunder from external foreign substances or the like. The lens protection layer 350 may be referred to as a lens protection member. In addition, the lens protection layer 350 may planarize a step generated by the lens 340. The lens protection layer 350 may extend from the display area DA into a partial area of the bezel area BZA1 and BZA2. In an example, the refractive index of the lens protection layer 350 may be lower than the refractive index of the lens 340. Accordingly, light having passed through the lens 340 may be prevented from being directed toward the substrate 205.

An insulating material having fluidity may be included in the lens protection layer 350. The lens protection layer 350 may include the insulating material having fluidity and thus be formed in a shape having an upper flat surface in the display area DA. An organic insulating material may be included in the insulating material having fluidity. For example, the organic insulating material may include at least one of epoxy, polyimide, polyethylene, and acrylate. However, the material is not limited thereto.

When the insulating material having fluidity flows to the outer area (or edge area) of the display panel 10, a height of a portion of the lens protection layer 350 disposed in a portion of the display area DA closer to the bezel area BZA1 and BZA2 may be reduced. As a result, the height uniformity between the height of a portion of the lens protection layer 350 in the central area of the display area DA and the height of a portion of the lens protection layer 350 in the portion of the display area DA close to the bezel area BZA1 and BZA2 may be deteriorated.

Accordingly, the display apparatus according to some implementations of the present disclosure may include a structure for controlling the flow of the insulating material having fluidity in the bezel area. In addition, the display apparatus according to implementations of the present disclosure may include a structure capable of preventing moisture from penetrating into the display area. Hereinafter, this will be described with reference to the drawings.

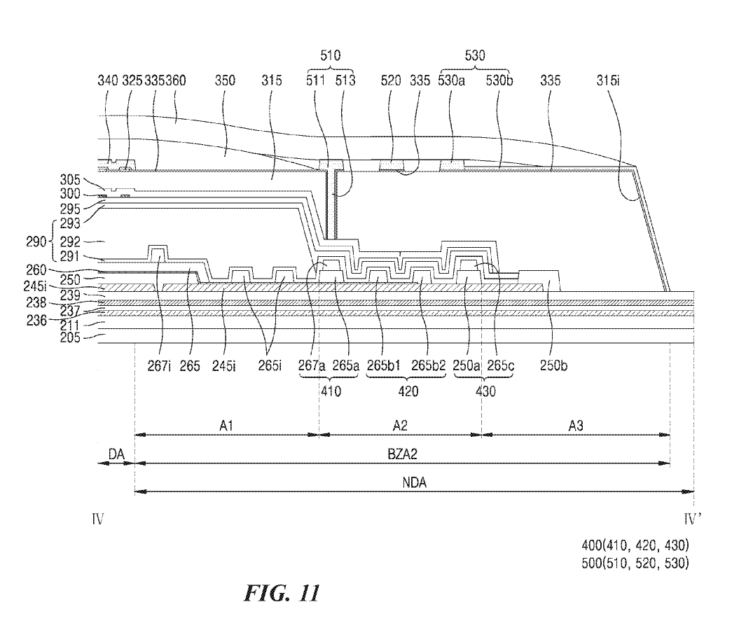

FIGS. 9 to 11 are diagrams illustrating a display apparatus according to an example implementation of the present disclosure. FIG. 9 is a cross-sectional view taken along a line III-III' of FIG. 2. FIG. 10 is an enlarged view of an area V of FIG. 9. FIG. 11 is a cross-sectional view taken along a line IV-IV' of FIG. 2.

For example, FIG. 9 may show a cross-section of a partial area disposed in one side in the second direction DR2 of the display area DA, and the non-display area NDA of the display panel 10 (see FIG. 2). FIG. 11 may illustrate a cross-section of a partial area disposed in each of the other side in the second direction DR2 and both opposing sides in the first direction DR1 of the display area DA, and the non-display area NDA of the display panel. In FIG. 10, the polarizing layer 360 is excluded for convenience of illustration. Since FIGS. 9 to 11 include the same components as those of FIG. 4, redundant descriptions thereof will be omitted or briefly set forth, and differences therebetween will be mainly described. Like reference numerals may denote like elements.

Referring to FIGS. 9 to 11, the first insulating structure 211 may be disposed on the substrate 205 and in the non-display area NDA. The first insulating structure 211 may include one or more insulating layers extending from the display area DA. For example, the first insulating structure 211 may include the first buffer layer 210, the second buffer layer 220, and the gate insulating layer 230. The first insulating structure 211 may be implemented as a single layer or a multilayer made of an inorganic insulating material such as silicon oxide (SiOx) or silicon nitride (SiNx). However, implementations of the present disclosure are not limited thereto.

The first intermediate electrode layer 236 may be disposed on the gate insulating structure 230 and in the non-display area NDA. In an example, the first intermediate electrode layer 236 may act as one of signal lines that transmit various signals. In the present disclosure, for convenience of description, an example implementation in which the first intermediate electrode layer 236 is made of the same material as that of the gate electrode 235 and be formed in the same process as the process for forming the gate electrode 235 will be described, but is not limited thereto. For example, the first intermediate electrode layer 236 may be made of the material different from that of the gate electrode 235 and be formed in the process different from that for forming the gate electrode 235. In addition, in the present disclosure, for convenience of description, an example implementation in which the first intermediate electrode layer 236 is implemented as a single layer has been described. However, implementation of the present disclosure are not limited thereto. For example, the first intermediate electrode layer 236 may be implemented as a stack of a plurality of layers.

The first interlayer insulating layer 237 may be disposed on the first intermediate electrode layer 236 and in the non-display area NDA. The first interlayer insulating layer 237 may include an inorganic insulating material and may extend from the display area DA. The second intermediate electrode layer 238 may be disposed on the first interlayer insulating layer 237 and in the non-display area NDA. The second intermediate electrode layer 238 may act as, for example, one of the signal lines for transmitting various signals. The second intermediate electrode layer 238 may extend into the pad area PDA.

The second interlayer insulating layer 239 may be disposed on the second intermediate electrode layer 238 and in the non-display area NDA. A signal line 245i may be disposed on the second interlayer insulating layer 239. The signal line 245i may be made of the same material as the material of the source/drain electrodes 245 and be formed in the same process as the process for forming the source/drain electrodes 245 (see FIG. 4). A pad electrode 245p made of the same material as that of the signal line 245i and be formed through the same process as the process for forming the signal line 245i may be disposed in the pad area PDA. The pad electrode 245p may be in contact with and electrically connected to the second intermediate electrode layer 238. Although not shown in the drawings, the pad electrode 245p may be connected to the printed circuit board via a flexible circuit board on which the driving circuit chip is disposed. Accordingly, the second intermediate electrode layer 238 may provide, to the display area DA, power or a data signal for driving the light-emitting element supplied from the driver disposed on the printed circuit board.

The planarization layer 250 may be disposed on the signal line 245i. The planarization layer 250 may be disposed in the display area DA and a portion of the bezel area BZA1 and BZA2. For example, a portion of the planarization layer 250 may act as a pad protection pattern 250p covering one side end of the pad electrode 245p. The first electrode 260 extending from the display area DA may be disposed on the planarization layer 250 and in the non-display area NDA. The first electrode 260 may extend into a portion of the bezel area BZA1 and BZA2. The bank 265 may be disposed on the first electrode 260 and in the non-display area NDA. The bank 265 may extend into a portion of the bezel area BZA1 and BZA2.

A plurality of barrier patterns 267i, 265i, and 250b may be disposed in the bezel area BZA1 and BZA2. Further, a plurality of first structures, such as a plurality of encapsulation dams 400, may also be disposed in the bezel area BZA1 and BZA2.

The bezel area BZA1 and BZA2 may include a first bezel area BZA1 and a second bezel area BZA2. For example, the first bezel area BZA1 may be positioned in one side of the display panel 10, and the second bezel area BZA2 may be positioned in three sides of the display panel 10, but is not limited thereto. For example, as illustrated in FIG. 2, the first bezel area BZA1 may be positioned in one side in the second direction DR2 of the display panel 10. The second bezel area BZA2 may be positioned in each of the other side in the second direction DR2, and each of both opposing sides in the first direction DR1 of the display panel 10. For example, the pad area PDA in which a plurality of pad electrodes 245p are disposed may be positioned in the first bezel area BZA1, but is not limited thereto.

Each of the bezel area BZA1 and BZA2 may include a first area A1, a second area A2, and a third area A3. The first area A1 of the bezel area BZA1 and BZA2 may be an area closest to the display area DA among the first to third areas. The third area A3 of the bezel area BZA1 and BZA2 may be an area closest to an edge portion (or an end) of the substrate 205 among the first to third areas. For example, as illustrated in FIG. 9, the third area A3 of the first bezel area BZA1 may be closer to the pad area PDA than each of the first and second areas A1 and A2 is. As illustrated in FIG. 11, the third area A3 of the second bezel area BZA2 may be an area closest to the end of the substrate 205 among the first to third areas. The second area A2 may be disposed between the first area A1 and the third area A3.

The plurality of barrier patterns 267i, 265i, and 250b and the plurality of encapsulation dams 400 may prevent the second encapsulation layer 292 including the organic insulating material from overflowing outwardly of the bezel area BZA1 and BZA2.

The plurality of barrier patterns 267i, 265i, and 250b may include a first barrier pattern 267i, a second barrier pattern 265i, and a third barrier pattern 250b. The first barrier pattern 267i may be positioned on the bank 265 and disposed in the first area A1 closest to the display area DA. The first barrier pattern 267i may be made of the same material as that of the spacer 267 and be formed through the same process as the process for forming the spacer 267 (see FIG. 4) of the display area DA, but is not limited thereto.

The plurality of encapsulation dams 400 may include a first encapsulation dam 410, a second encapsulation dam 420, and a third encapsulation dam 430. The first encapsulation dam 410, the second encapsulation dam 420, and the third encapsulation dam 430 may be arranged to be spaced apart from each other by a predetermined spacing in a direction from the first area of the bezel area BZA1 and BZA2 that is adjacent to the display area DA to the side end of the substrate 205 or the display panel. The second encapsulation dam 420 may be disposed between the first encapsulation dam 410 and the third encapsulation dam 430.

The first encapsulation dam 410 may be disposed in a boundary area between the first area A1 and the second area A2. For example, the first encapsulation dam 410 may be disposed in second area A2 and in a boundary area between the first area A1 and the second area A2. The first encapsulation dam 410 may have a structure in which a first layer 265a as a lower layer and a second layer 267a as an upper layer are stacked. For example, the first layer 265a may be made of the same material as that of the bank 265 and be formed in the same process as the process for forming the bank 265, but is not limited thereto. The second layer 267a may be made of the same material as that of the first barrier pattern 267i and be formed through the same process as the process for forming the first barrier pattern 267i, but is not limited thereto.

For example, the first layer 265a may be made of the material different from that of the bank 265 and be formed in the process different from that for forming the bank 265, but is not limited thereto. The second layer 267a may be made of the material different from that of the first barrier pattern 267i and be formed in the process different from that for forming the first barrier pattern 267i.

The second barrier pattern 265i may be disposed in the first area A1. For example, the second barrier pattern 265i may be disposed between the first encapsulation dam 410 and the first barrier pattern 267i. The second barrier pattern 265i may be made of the same material as that of the bank 265 and be formed in the same process as the process for forming the bank 265. In an example, the second barrier pattern 265i may be disposed such that a plurality of patterns are spaced apart from each other.

The third encapsulation dam 430 may be disposed in a boundary area between the second area A2 and the third area A3 of the bezel area BZA1 and BZA2. For example, the third encapsulation dam 430 may be disposed in the second area A2 and in a boundary area between the second area A2 and the third area A3 of the bezel area BZA1 and BZA2. The third encapsulation dam 430 may be spaced apart from the first encapsulation dam 410 while the encapsulation dam 430 is disposed between the first encapsulation dam 410 and the end of the substrate 205. The third encapsulation dam 430 may have a structure in which a first layer 250a as a lower layer and a second layer 265c as an upper layer are stacked. For example, the first layer 250a of the third encapsulation dam 430 may be made of the same material as that of the planarization layer 250 and be formed in the same process as the process for forming the planarization layer 250, but is not limited thereto. The second layer 265c of the third encapsulation dam 430 may be made of the same material as that of the bank 265 and be formed in the same process as the process for forming the bank 265, but is not limited thereto.

The second encapsulation dam 420 may be disposed in the second area A2. The second encapsulation dam 420 may be disposed between the first encapsulation dam 410 and the third encapsulation dam 410. The second encapsulation dam 420 may include a plurality of patterns 265b1 and 265b2 spaced apart from each other in the horizontal direction. The plurality of patterns 265b1 and 265b2 may be made of the same material as that of the bank 265 and be formed in the same process as the process for forming the bank 265, but is not limited thereto. The plurality of patterns 265b1 and 265b2 may include a first pattern 265b1 and a second pattern 265b2. However, implementations of the present disclosure are not limited thereto, and at least three patterns may be included therein. Each of the first pattern 265b1 and the second pattern 265b2 may have a line shape extending along the periphery of the display area DA and surrounding the display area DA. The second pattern 265b2 may be positioned outwardly of the first pattern 265b1, and the second pattern 265b2 may be positioned inwardly of the third encapsulation dam 430.

The third barrier pattern 250b may be disposed outwardly of the third encapsulation dam 430. For example, the third barrier pattern 250b may be disposed in the third area A3 as an edge area of the bezel area BZA1 and BZA2. The third barrier pattern 250b may be made of the same material as that of the planarization layer 250 and be formed through the same process as the process for forming the planarization layer 250, but is not limited thereto. The third barrier pattern 250b may cover an end of the signal line 245i extending into the bezel area BZA1 and BZA2.

Each of the first encapsulation layer 291, the second encapsulation layer 292, and the third encapsulation layer 293 may extend from the display area DA into the bezel area BZA1 and BZA2. The first encapsulation layer 291 may cover the first barrier pattern 267i, the second barrier pattern 265i, the first encapsulation dam 410, the second encapsulation dam 420, and the third encapsulation dam 430. The third encapsulation layer 293 may be disposed on the second encapsulation layer 292 in the first area A1 of the bezel area BZA1 and BZA2, and may be in contact with the first encapsulation layer 291 in the second area A2 and the third area A3. An inorganic insulating material may be included in each of the first encapsulation layer 291 and the third encapsulation layer 293. The second encapsulation layer 292 may be disposed between the first encapsulation layer 291 and the third encapsulation layer 293. For example, in the first area A1 of the bezel area BZA1 and BZA2, the second encapsulation layer 292 may be disposed between the first encapsulation layer 291 and the third encapsulation layer 293, but is not limited thereto.

The first touch buffer layer 295 may be disposed on the third encapsulation layer 293 and in the non-display area NDA. The first touch buffer layer 295 may include an inorganic insulating material.

A plurality of bridge electrodes 300 may be disposed on the first touch buffer layer 295. Some areas of the plurality of bridge electrodes 300 may extend into the bezel area BZA1 and BZA2 and then into the pad area PDA. A partial area of the bridge electrode 300 extending into the pad area PDA may be referred to as a bridge link line 300a. The bridge link line 300a may be in contact with and electrically connected to the pad electrode 245p in the pad area PDA. The bridge link line 300a may transmit a touch driving signal from the driving circuit chip or the driver disposed on the printed circuit board to the display area DA. Accordingly, the bridge link line 300a may be disposed in one side in the first direction DR1 of the display panel DP as shown in FIG. 9, and may not be disposed in each of the other side in the first direction DR1 and both opposing sides in the second direction DR2 of the display panel DP as shown in FIG. 11.

The second touch buffer layer 305 may be disposed on the plurality of bridge electrodes 300 and the bridge link line 300a. The second touch buffer layer 305 may extend into the bezel area BZA1 and BZA2 while covering the plurality of bridge electrodes 300 and the bridge link line 300a. The second touch buffer layer 305 may be conformally formed on each of the first touch buffer layer 295 and the third encapsulation layer 293 disposed thereunder. The second touch buffer layer 305 may cover the bridge link line 300a disposed in the pad area PDA. The second touch buffer layer 305 may include an inorganic insulating material.

The touch insulating layer 315 may be disposed on the second touch buffer layer 305 and in the non-display area NDA. The touch insulating layer 315 may extend from the display area DA into the bezel area BZA1 and BZA2. A side end of the touch insulating layer 315 extending into the bezel area BZA1 and BZA2 may be implemented to have an inclined surface 315i having a slope. In addition, in the first bezel area BZA1, the side end of the touch insulating layer 315 may define a boundary area between the third area A3 and the pad area PDA. In addition, in the second bezel area BZA2, the side end of the touch insulating layer 315 may be positioned inwardly the side end of the substrate 205. For example, the side end of the touch insulating layer 315 may be positioned in the third area A3 of the bezel area BZA1 and BZA2.

The touch insulating layer 315 may have a sufficient thickness to planarize a step caused by the underlying structure. The touch insulating layer 315 may include an organic insulating material. At least one trench 315t may be defined in the touch insulating layer 315. The trench 315t may vertically extend through the touch insulating layer 315 in a direction toward the substrate 205 and may expose a portion of an upper surface of the second touch buffer layer 305. The trench 315t may have a pillar shape vertically extending through the touch insulating layer 315 in a cross-sectional view. The trench 315t may be disposed to overlap the first encapsulation dam 410 of the plurality of encapsulation dams 400 in the vertical direction. The trench 315t may have a ring shape surrounding an outer periphery of the display area AA in the plan view. For example, the trench 315t may have a closed loop line shape in the plan view.

The plurality of touch electrodes 325 may be disposed on the touch insulating layer 315 and in the display area DA. The passivation layer 335 may be disposed on the touch electrode 325 and in the non-display area NDA. The passivation layer 335 may extend from the display area DA into the bezel area BZA1 and BZA2. The passivation layer 335 may be disposed on an upper surface of the touch insulating layer 315 made of an organic insulating material in the bezel area BZA1 and BZA2. The passivation layer 335 may be disposed on a surface of the touch insulating layer 315 exposed through the trench 315t. The passivation layer 335 may not cover a portion of an upper surface of the touch insulating layer 315 so as to be exposed in the second area A2 of the bezel area BZA1 and BZA2. The passivation layer 335 may cover the inclined surface 315i of the touch insulating layer 315 in the third area A3 of the bezel area BZA1 and BZA2. The passivation layer 335 may be made of an inorganic insulating material to prevent moisture or foreign matter from penetrating into the touch insulating layer 315.

The passivation layer 335 may be constituted by a single layer made of a silicon oxide (SiOx) film, a silicon nitride (SiNx) film, or a silicon oxynitride (SiOxNy) film or a multilayer film thereof, etc.

The lens 340 may be disposed on the passivation layer 335 and in the display area DA. The portion of the display area DA illustrated in FIGS. 9 and 11 may be an edge portion of the display area DA adjacent to the bezel area BZA1 and BZA2. Accordingly, the lens 340 disposed in the edge portion of the display area DA may act as a dummy pattern or lens.

The lens protection layer 350 may be disposed on the lens 340. The lens protection layer 350 may be formed by applying an insulating material having fluidity to planarize a step caused by the lens 340 or the like disposed thereunder. When a structure controlling the flow of the insulating material having the fluidity is absent in the bezel area BZA1 and BZA2, the insulating material having the fluidity may spread into the outer area of the display panel due to the fluidity of the material. For example, the insulating material having fluidity may flow to the third area A3 of the bezel area BZA1 and BZA2 adjacent to the side end of the substrate 205. As a result, the height of the portion of the lens protection layer 350 in the edge of the display area DA close to the bezel area BZA1 and BZA2 may be reduced. Thus, the height uniformity of the lens protection layer 350 in the entire area of the display area DA may deteriorate.

Accordingly, the structure for controlling the flow of the insulating material having fluidity may be disposed on the passivation layer 335 and in the bezel area BZA1 and BZA2. For example, the structure for controlling the flow of the insulating material having fluidity may be implemented as a plurality of second structures, such as the plurality of lens dams 500. The plurality of lens dams 500 may include a first lens dam 510, a second lens dam 520, and a third lens dam 530. For example, the first lens dam 510 may be disposed in the second area A2 to overlap one of the plurality of encapsulation dams 400 in a vertical direction. For example, the first lens dam 510 may be disposed to overlap with the first encapsulation dam 410, but is not limited thereto. The second lens dam 520 may be disposed outwardly of the first lens dam 510. The third lens dam 530 may be disposed outwardly of the second lens dam 520. Adjacent ones of the lens dams 510, 520, and 530 may be arranged to be spaced apart from each other by a predetermined spacing. For example, each of the lens dams 510, 520, and 530 may have a line shape continuously extending around the display area DA in the plan view. For example, each of the lens dams 510, 520, and 530 may extend so as not to be broken but to form a closed loop in the plan view. In an example, the plurality of lens dams 500 may have the same thickness. However, implementations of the present disclosure are not limited thereto.

Each of the plurality of lens dams 500 may be made of the same material as that of the lens 340 and be formed in the same process as the process for forming the lens 340 of the display area DA, but is not limited thereto. Accordingly, the display apparatus according to some implementation of the present disclosure may reduce the number of the process steps, such that there is an effect that the production energy required for the production of the display apparatus may be reduced, thereby reducing the light-emission of greenhouse gas.

The plurality of lens dams 500 may be positioned in the bezel area BZA1 and BZA2. At least one of the plurality of lens dams 500 may be disposed in the second area A2 of the bezel area BZA1 and BZA2 in which the encapsulation dams 410, 420, and 430 are disposed, but is not limited thereto.

Referring to FIG. 10, the first lens dam 510 may be disposed to overlap the first encapsulation dam 410 disposed in the second area A2 in the vertical direction. The first lens dam 510 may include a first head portion 511 and a first pillar portion 513. The first pillar portion 513 of the first lens dam 510 may fill the trench 315t. The first head portion 511 of the first lens dam 510 may be integrally formed with the first pillar portion 513 and may be disposed on the top surface of the first pillar portion 513. The first head portion 511 may extend on and along the upper surface of the touch insulating layer 315.

The trench 315t may have the same shape as that of the first pillar portion 513 of the first lens dam 510 in the cross-sectional view. In a plan view, the trench 315t may have a line shape continuously extending around the display area DA. For example, in the plan view, the trench 315t may extend so as not be broken but to form a closed loop.

For example, a first width 510w of the first head portion 511 of the first lens dam 510 may have a size in a range of 40 ㎛ to 55 ㎛. In this regard, the width may refer to a width in the direction from the lens to the side end of the substrate. However, implementations of the present disclosure are not limited to the above numerical value. A height of the first head portion 511 of the first lens dam 510 may be smaller than the first width 510w. The height of the first head portion 511 may be a vertical length between the upper surface of the touch insulating layer 315 and an upper surface of the first head portion 511. For example, the height of the first head portion 511 of the first lens dam 510 may be in a range of 10 ㎛ to 15 ㎛. Each of the width and the height of each of the second lens dam 520 and the third lens dam 530 may be equal to each of the first width 510w and the height of the first head portion 511 of the first lens dam 510. Accordingly, the width of each of the lens dams 510, 520, and 530 may be greater than the height thereof. In this case, the contact area of the polarizing layer 360 to be described later in contact with each of the lens dams 510, 520, and 530 increases, the occurrence of the peel-off defect of the polarizing layer 360 may be prevented.

The first lens dam 510 may be a structure which the insulating material having fluidity spreading from the display area DA first contacts in the bezel area BZA1 and BZA2.

Therefore, it is preferable that an upper surface of the first head portion 511 of the first lens dam 510 is positioned at a higher vertical level than a vertical level of an upper surface of each of the second and third lens dams 520 and 530 so as to control the flow of the insulating material having fluidity. Accordingly, the height of the first lens dam 510 may be the largest, and the height of the third lens dam 530 may be the smallest. The height of the second lens dam 520 may be smaller than the height and greater than the height, but is not limited thereto.

For example, when a portion of the upper surface of the first head portion 511 of the first lens dam 510 corresponding to the largest thickness and a portion of an upper surface of the first encapsulation dams 410 disposed thereunder corresponding to the largest thickness overlap each other in the vertical direction, the upper surface of the first head portion 511 of the first lens dam 510 may be positioned at a higher vertical level than a vertical level of an upper surface of each of the second and third lens dams 520 and 530. The height of the first head portion 511 of the first lens dam 510 may be maintained at a size capable of controlling the flow of the flowable insulating material. As a result, the first head portion 511 of the first lens dam 510 may first prevent the insulating material having fluidity from overflowing over the second lens dam 520 or the third lens dam 530. For example, the portion of the upper surface of the first head portion 511 of the first lens dam 510 corresponding to the largest thickness may be a central portion thereof through which a first center line C1 of the first width 510w vertically passes. In addition, the portion of the upper surface of the first encapsulation dam 410 corresponding to the greatest thickness may be a central portion thereof through which a second central line C2 of the second width 410w vertically passes. Each of the first center line C1 and the second center line C2 may be a virtual line vertically passing through each of the first lens dam 510 and the first encapsulation dam 410. The first center line C1 may coincide with a center line vertically passing through a center in a width direction of the first pillar portion 513 of the first lens dam 510. However, implementations of the present disclosure are not limited thereto.

The first center line C1 of the first width 510w of the first head portion 511 of the first lens dam 510 may coincide with the second center line C2 of the second width 410w of the first encapsulation dam 410. Accordingly, the flow of the insulating material having fluidity may be controlled by the first lens dam 510 overlapping the first encapsulation dam 410 in the vertical direction and having the upper surface positioned at a higher vertical level than a vertical level of an upper surface of each of the second and third lens dams 520 and 530.

As described above, the passivation layer 335 may not cover a portion of the upper surface of the touch insulating layer 315 so as to be exposed in the second area A2 of the bezel area BZA1 and BZA2. The passivation layer 335 may be partially removed in the second area A2 in the process of forming the plurality of lens dams 510, 520, and 530 while a protective mask process is omitted. Accordingly, the portion of the upper surface of the touch insulating layer 315 disposed between the first lens dam 510 and the second lens dam 520, and the portion of the upper surface of the touch insulating layer 315 disposed between the second lens dam 520 and the third lens dam 530 may not be covered with the passivation layer 335 so as to be exposed.

In the second area, the passivation layer 335 may be partially removed to expose the portion of the upper surface of the touch insulating layer 315 made of the organic insulating material. Moisture may penetrate into the organic insulating material in a high temperature and high humidity environment. Thus, the touch insulating layer 315 made of the organic insulating material may act as a moisture penetration path through which the moisture flows. The touch insulating layer 315 extends into the display area DA, such that the metal lines in the display area DA may be exposed to the moisture. When the metal line such as a touch line in the display area DA is exposed to the moisture, there may be a problem in that the metal line undergoes electrolytic corrosion or is corroded.

Accordingly, in the display apparatus according to an example implementation of the present disclosure, the trench 315t may prevent the touch insulating layer 315 from acting as the moisture penetration path. For example, as shown in FIGS. 9 and 10, the trench 315t may be disposed at a position between the first area A1 relatively close to the display area DA and the second area A2. The trench 315t may divide the touch insulating layer 315 into two portions isolated from each other. Thus, the trench 315t may interrupt the continuity of the touch insulating layer 315 and may allow the touch insulating layer 315 to be broken or discontinuous. Accordingly, as indicated by the arrow in FIG. 10, the first trench 315t may block the flow of the moisture penetrating through the exposed portion of the upper surface of the touch insulating layer 315 disposed between the first lens dam 510 and the second lens dam 520 so as not to invade into the display area DA.

In addition, the surface of the touch insulating layer 315 exposed through the trench 315t may be covered with the passivation layer 335 made of the inorganic insulating material. Accordingly, the flow of the moisture may be prevented by the passivation layer 335 formed in the trench. In addition, the trench 315t may be filled with the pillar portion of the first lens dam 510. The first lens dam 510 may include an organic insulating material having the second density that is relatively higher than the first density of the touch insulating layer 315. Accordingly, the first pillar portion of the first lens dam 510 filling the trench 315t may further prevent the moisture from permeating into the display area DA. Accordingly, the display apparatus satisfying a high reliability may be achieved by preventing the moisture permeating from the outside out of the display apparatus from flowing toward the display area DA. In an example, the trench 315t may have a pillar shape extending through the touch insulating layer 315 and vertically extending so as to be aligned with the first center line C1 and the second center line C2.

If the first lens dam 510 is disposed in the third area A3 that is positioned outwardly of the second area A2 in which the encapsulation dams 410, 420, and 430 are disposed, the insulating material having fluidity flows to the third area A3. Then, the uniformity between the thickness of the portion of the lens protection layer 350 in the central area of the display area DA and the thickness of the portion of the lens protection layer 350 in the edge portion of the display area DA close to the bezel area BZA1 and BZA2 may be deteriorated. Then, since the thickness of the lens protection layer 350 is not sufficiently secured in the edge area of the display area, there is a problem in that a portion of the lens 340 in the edge area of the display area is not protected by the lens protection layer 350 occurs. In addition, if the lens dams 510, 520, and 530 are disposed in the third area A3, a problem in which the insulating material having fluidity overflows may occur. Accordingly, it is preferable that at least one of the plurality of lens dams 500 is disposed in the second area A2 in which the encapsulation dams 410, 420, and 430 are disposed.

The second lens dam 520 may be disposed outwardly of the first lens dam 510.

The third lens dam 530 may be disposed outwardly of the second lens dam 520. It is preferable that at least one of the lens dams 510, 520, and 530 is disposed in the second area A2 in which the encapsulation dams 410, 420, and 430 are disposed. For example, the first lens dam 510 may be disposed in the second area A2. The third lens dam 530 may include a first pattern portion 530a and a second pattern portion 530b. The first pattern portion 530a may have the same shape as that of the first lens dam 510 or the second lens dam 520. For example, the first pattern portion 530a may have the same shape as that of the first head portion 511 of the first lens dam 510 or the second lens dam 520. For example, the first pattern portion 530a may have a trapezoidal shape in the cross-sectional view. However, implementations of the present disclosure are not limited thereto.

The second pattern portion 530b of the third lens dam 530 may be implemented as an extension pattern extending outwardly from one side surface of the first pattern portion 530a. The second pattern portion 530b may extend toward the edge portion (or the side end) of the substrate 205. For example, the second pattern portion 530b may extend along and on the inclined surface 315i of the touch insulating layer 315. The touch electrode 325 may extend from the display area DA onto the edge portion (or the side end) of the substrate 205.

The second pattern portion 530b may cover the touch electrode (or a metal line) positioned on an edge area (or the end area) of the substrate 205 to prevent damage to the touch electrode from external impact, moisture penetration, or the like. This may prevent the occurrence of the touch operation failure due to damage to the touch electrode, thereby improving product reliability. The first pattern portion 530a and the second pattern portion 530b may be integrally formed with each other. The second pattern portion 530b may be formed in a halftone manner.

The polarization layer 360 may be disposed on the lens protection layer 350. The polarizing layer 360 may disposed across the display area DA, and the first area A1, the second area A2, and the third area A3 of the bezel area BZA1 and BZA2. The lens protection layer 350 may not be disposed beyond the first area A1 of the bezel area BZA1 and BZA2. In addition, the upper surface of the second pattern portion 530b disposed in the third area A3 and the upper surface of the first pattern portion 530a may be disposed at different vertical levels. For example, the upper surface of the second pattern portion 530b disposed in the third area A3 may be positioned at a lower vertical level than a vertical level of the upper surface of the first pattern portion 530a, but is not limited thereto. Accordingly, the upper surface of the display area DA and the upper surfaces of the first area A1 to the third area A3 of the bezel area BZA1 and BZA2 may be disposed at different vertical levels.

The plurality of lens dams 500 may be disposed between the first area A1 and the third area A3. For example, the plurality of lens dams 500 may be disposed in the second area A2. The polarizing layer 360 may continuously extend across the first area A1 to the third area A3 while being in contact with the plurality of lens dams 500 disposed in the second area A2. The inclination of the polarizing layer 360 may be gradually reduced from the first area A1 toward the third area A3. The polarizing layer 360 may be attached in close contact to the second pattern portion 530b of the third lens dam 530 disposed in the edge portion of the third area A3 and thus may not lift off. Accordingly, a defect in which the polarizing layer 360 lifts off due to a step may be prevented from occurring.

The trench blocking the moisture path through which moisture penetrates into the display area DA may have various shapes. Hereinafter, this will be described with reference to the drawings.

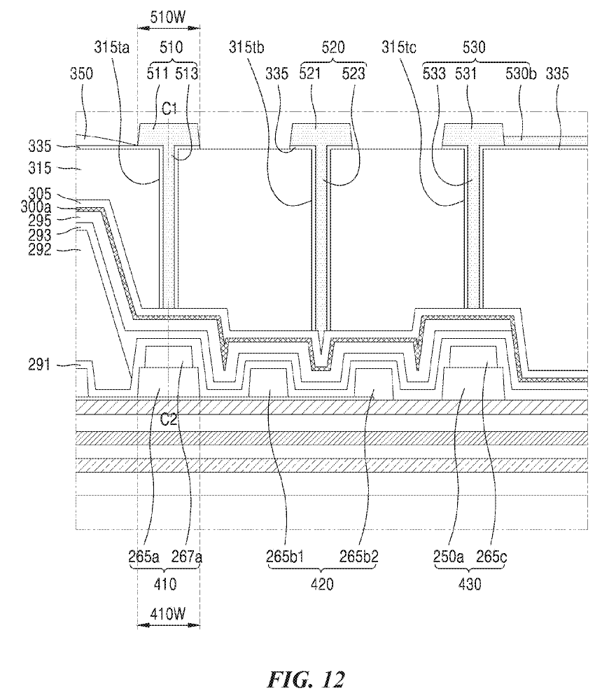

FIGS. 12 to 14 are respectively diagrams illustrating display apparatuses according to some further implementation of the present disclosure. FIGS. 12 to 14 include the same components as those of FIGS. 9 to 11 except for the lens dams. Thus, redundant descriptions thereof will be omitted or briefly set forth, and differences therebetween will be described. Like reference numerals may denote like elements.

Referring to FIG. 12, a plurality of trenches 315ta, 315tb, and 315tc may be formed in the touch insulating layer 315. Accordingly, in the display apparatus according to an example implementation of the present disclosure, the plurality of trenches 315ta, 315tb, and 315tc may prevent the touch insulating layer 315 from acting as the moisture penetration path. Each of the plurality of trenches 315ta, 315tb, and 315tc may vertically extend through the touch insulating layer 315 toward the substrate 205 and may expose a portion of the upper surface of the second touch buffer layer 305. The trenches 315ta, 315tb, and 315tc may be arranged to be spaced apart from each other by a predetermined spacing. The trenches 315ta, 315tb, and 315tc may be spaced apart from each other in a direction toward the third area A3 of the bezel area BZA1 and BZA2. At least one of the trenches 315ta, 315tb, and 315tc may be disposed to overlap at least of the plurality of encapsulation dams 400 in the vertical direction. For example, the first trench 315ta among the plurality of trenches 315ta, 315tb, and 315tc may be disposed to overlap the first encapsulation dam 410 among the plurality of encapsulation dams 400 in the vertical direction.

The second trench 315tb among the plurality of trenches 315ta, 315tb, and 315tc may be disposed to overlap an area between the first pattern 265b1 and the second pattern 265b2 of the second encapsulation dam 420 in the vertical direction. However, implementations of the present disclosure are not limited thereto. The third trench 315tc among the plurality of trenches 315t may be disposed to overlap the third encapsulation dam 430 among the plurality of encapsulation dams 400 in the vertical direction.

Each of the trenches 315ta, 315tb, and 315tc may have a line shape surrounding the outer periphery of the display area AA. For example, in a plan view, each of the trenches 315ta, 315tb, and 315tc may have a line shape continuously extending around the display area DA. For example, in the plan view, each of the trenches 315ta, 315tb, and 315tc may extend so as not be broken but to form a closed loop. The passivation layer 335 may be disposed on a surface of the touch insulating layer 315 exposed through each of the trenches 315ta, 315tb, and 315tc.

One lens dam may be disposed in one trench. For example, the first trench 315ta may be filled with the first pillar portion 513 of the first lens dam 510, and the first head portion 511 of the first lens dam 510 may be disposed on a top surface of the first pillar portion 513. For example, the first trench 315ta may have the same shape as that of the first pillar portion 513 of the first lens dam 510 in the cross-sectional view. The second trench 315tb may be filled with a second pillar portion 523 of the second lens dam 520, and a second head portion 521 of the second lens dam 520 may be disposed on a top surface of the second pillar portion 523. For example, the second trench 315tb may have the same shape as that of the second pillar portion 523 of the second lens dam 520 in the cross-sectional view. The third trench 315tc may be filled with a third pillar portion 533 of the third lens dam 530, and a third head portion 531 of the third lens dam 530 may be disposed on a top surface of the third pillar portion 533. For example, the third trench 315tc may have the same shape as that of the third pillar portion 533 of the third lens dam 530 in the cross-sectional view. The third lens dam 530 may include a second pattern portion 530b extending outwardly from one side surface of the third head portion 531. The second pattern portion 530b may extend toward an edge portion (or the side end) of the substrate 205. The vertical level of the upper surface of the second pattern portion 530b may be lower than the vertical level of the upper surface of the third head portion 531.

The upper surface of the first head portion 511 of the first lens dam 510 may be positioned at a vertical level higher than a vertical level of the upper surface of each of the second head portion 521 of the second lens dam 520 and the third head portion 531 of the third lens dam 530 in order to prevent the lens protection layer 350 from overflowing to the outer area of the display panel. To this end, the first center line C1 of the first width 510w of the first head portion 511 of the first lens dam 510 may coincide with the second center line C2 of the second width 410w of the first encapsulation dam 410 positioned thereunder.

In the bezel area BZA1 and BZA2, the multi-trenches 315ta, 315tb, and 315tc may be formed in the touch insulating layer 315 and be arranged in the direction toward the side end of the substrate 205 away from the display area DA. Accordingly, the moisture path through which moisture penetrates into the display area DA is blocked in a multiple manner, thereby preventing the phenomenon that the metal line undergoes electrolytic corrosion or is corroded. Thus, the reliability of the product may be improved.

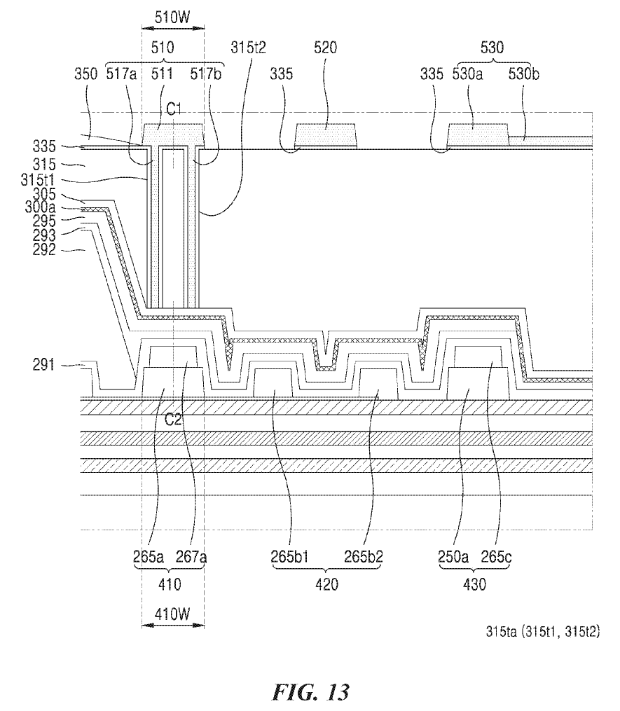

Referring to FIG. 13, at least one trench 315ta may be defined in the touch insulating layer 315. The trench 315ta may vertically extend through the touch insulating layer 315 to expose a portion of the upper surface of the second touch buffer layer 305. The trench 315ta may be disposed to overlap the first encapsulation dam 410 of the plurality of encapsulation dams 400 in the vertical direction. The trench 315ta may have a closed loop line shape continuously extending along the outer periphery of the display area AA. The trench 315ta may include a first trench pattern 315t1 and a second trench pattern 315t2 arranged so as to be spaced from each other in the direction from the lens to the side end of the substrate. In an example, an entirety of a combination of the first trench pattern 315t1 and the second trench pattern 315t2 of the trench 315ta may be contained in an area overlapping the first encapsulation dam 410. The passivation layer 335 may be disposed on a surface of the touch insulating layer 315 exposed through each of the first trench pattern 315t1 and the second trench pattern 315t2 of the trench 315ta.

The plurality of lens dams 510, 520, and 530 may be disposed on the touch insulating layer 315. The first lens dam 510 may include first pillar portions 517a and 517b and the first head portion 511. The first pillar portions 517a and 517b may include a (1-1)th pillar portion 517a and a (1-2)th pillar portion 517b filling the first trench pattern 315t1 and the second trench pattern 315t2 of the trench 315ta, respectively. The first pillar portions 517a and 517b and the first head portion 511 may be integrally formed with each other. In an example, the (1-1)th pillar portion 517a and the (1-2)th pillar portion 517b may be respectively disposed on both opposing side edges of the bottom surface of the first head portion 511. The first head portion 511 may extend onto the upper surface of the touch insulating layer 315. The first center line C1 of the first width 510w of the first head portion 511 of the first lens dam 510 may coincide with the second center line C2 of the second width 410w of the first encapsulation dam 410 positioned thereunder.

The second lens dam 520 and the third lens dam 530 may be disposed on the upper surface of the touch insulating layer 315.

In the display device according to another example implementation of the present disclosure, the trench 315ta including the multiple trench patterns 315t1 and 315t2 arranged in the direction from the lens to the side end of the substrate may be defined in the touch insulating layer 315 such that the moisture may be prevented from penetrating into the display area DA in the multiple manner. For example, the moisture path through which moisture penetrates into the display area DA is blocked by the multiple trench patterns 315t1 and 315t2 in the multiple manner, thereby preventing the phenomenon that the metal line undergoes electrolytic corrosion or is corroded. Thus, the occurrence of the touch operation failure of the display apparatus may be suppressed, thereby improving the reliability of the product. In addition, the trench 315ta including the multiple trench patterns 315t1 and 315t2 may be defined only in one of the plurality of lens dams 510, 520, and 530. For example, the trench 315ta may be defined only in the first lens dam 510 among the plurality of lens dams 510, 520, and 530, thereby simplifying the manufacturing process. However, implementations of the present disclosure are not limited thereto.

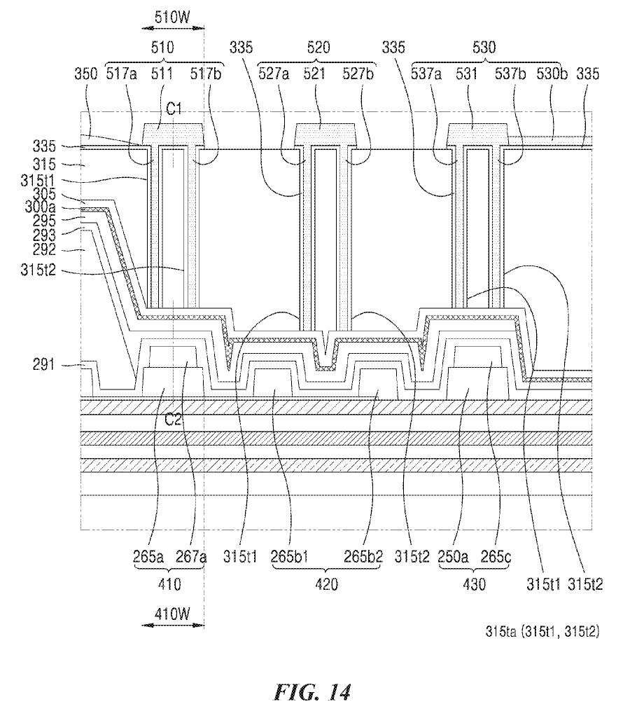

In another example, the trench 315ta including the multiple trench patterns 315t1 and 315t2 may be defined in each of the plurality of lens dams 510, 520, and 530. For example, as shown in FIG. 14, a structure in which the trench 315ta includes the first trench pattern 315t1 and the second trench pattern 315t2 may be applied not only to the first lens dam 510, but also to each of the second lens dam 520 and the third lens dam 530. For example, the second lens dam 520 may include second pillar portions 527a and 527b and the second head portion 521 that fill the trench 315tb. The second pillar portions 527a and 527b may include a (2-1)th pillar portion 527a and a (2-2)th pillar portion 527b filling the first trench pattern 315t1 and the second trench pattern 315t2 of the trench 315tb, respectively. The second column portions 527a and 527b and the second head portion 521 may be integrally formed with each other. In an example, the (2-1)th pillar portion 527a and the (2-2)th pillar portion 527b may be respectively disposed on both opposing side edges of the bottom surface of the second head portion 521.

The third lens dam 530 may include third pillar portions 537a and 537b and the third head portion 531 filling the trench 315tc. The third pillar portions 537a and 537b may include a (3-1)th pillar portion 537t1 and a (3-2)th pillar portion 537t2 filling the first trench pattern 315t1 and the second trench pattern 315t2 of the trench 315tc, respectively. The third pillar portions 537a and 537b and the third head portion 531 may be integrally formed with each other. In an example, the (3-1)th pillar portion 537a and the (3-2)th pillar portion 537b may be respectively disposed on both opposing side edges of the bottom surface the third head portion 531.

The first center line C1 of the first width 510w of the first head portion 511 of the first lens dam 510 may coincide with the second center line C2 of the second width 410w of the first encapsulation dam 410 positioned thereunder.

In the display apparatus according to another example implementation of the present disclosure, in the bezel area BZA1 and BZA2, a plurality of trenches 315ta to 315tc defined in the touch insulating layer 315 may be arranged in the direction toward the side end of the substrate 205 away from the display area DA such that each of the plurality of trenches 315ta to 315tc includes double trenches arranged in the direction toward the side end of the substrate 205. Accordingly, the moisture path through which moisture penetrates into the display area DA is blocked in the multiple manner, thereby preventing the phenomenon that the metal line undergoes electrolytic corrosion or is corroded. Thus, the occurrence of the touch operation failure of the display apparatus may be suppressed, thereby improving the reliability of the product.

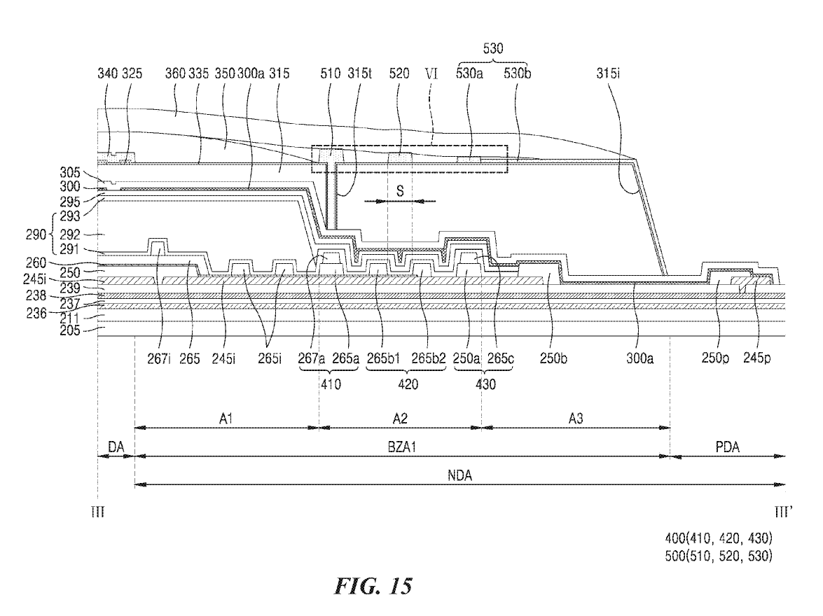

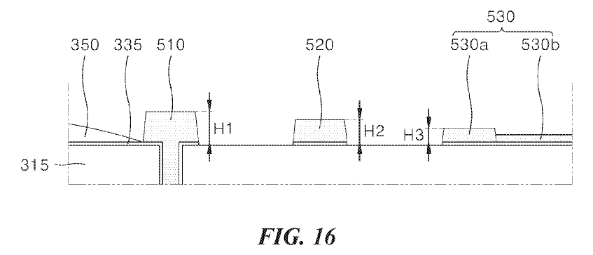

FIGS. 15 and 16 are respectively diagrams illustrating display apparatuses according to some still further implementations of the present disclosure. FIG. 15 is a cross-sectional view taken along a line III-III' of FIG. 2. FIG. 16 is an enlarged view of an area VI of FIG. 15. FIGS. 15 and 16 include the same components as those of FIGS. 9 to 11 except for the lens dams. Thus, redundant descriptions thereof will be omitted or briefly set forth, and differences therebetween will be described. Like reference numerals may denote like elements.

Referring to FIGS. 15 and 16, the plurality of touch electrodes 325 may be disposed on the touch insulating layer 315 covering the underlying structures. At least one trench 315t for dividing the touch insulating layer 315 into the portions spaced from each other may be defined in the touch insulating layer 315. The touch electrode 325 may be disposed in the display area DA. The passivation layer 335 may be disposed on the touch electrodes 325. The passivation layer 335 may extend from the display area DA into the third area A3 of the bezel area BZA1 and BZA2 so as to cover the inclined surface 315i of the touch insulating layer 315. The passivation layer 335 may include an inorganic insulating material.

The plurality of lens dams 500 may be disposed on the passivation layer 335. The plurality of lens dams 500 may include the first lens dam 510, the second lens dam 520, and the third lens dam 530. Each of the plurality of lens dams 500 may be made of the same material as that of the lens 340 of the display area DA and be formed in the same process as the process for forming the lens 340 of the display area DA, but is not limited thereto.

The first lens dam 510 may include the first pillar portion 513 filling the trench 315t and the first head portion 511 disposed on the top surface of the first pillar portion 513. The first lens dam 510, the second lens dam 520, and the third lens dam 530 may be arranged to be spaced apart from each other in the bezel area BZA1 and BZA2. At least one of the plurality of lens dams 500 may be disposed in the second area A2 of the bezel area BZA1 and BZA2 in which the encapsulation dams 410, 420, and 430 are disposed. For example, the first lens dam 510 may be disposed to overlap the first encapsulation dam 410 disposed in the second area A2 in the vertical direction. For example, as illustrated in FIG. 10, the first center line C1 of the first width WD1 of the first lens dam 510 may coincide with the second center line C2 of the second width 410w of the first encapsulation dam 410 positioned thereunder.

The lens dams 510, 520, and 530 may have different heights H1, H2, and H3, respectively. Referring to FIG. 16, the first lens dam 510 may have a first height H1, the second lens dam 520 may have a second height H2, and the third lens dam 530 may have a third height H3.

The first lens dam 510 may be a structure which the insulating material having fluidity spreading from the display area DA first contacts in the bezel area BZA1 and BZA2. Therefore, it is preferable that the upper surface of the first head portion 511 of the first lens dam 510 is positioned at a higher vertical level than a vertical level of each of the upper surface of each of the second and third lens dams 520 and 530 so as to control the flow of the insulating material having fluidity. For example, the first height H1 of the first lens dam 510 may be the largest. The height of each of the second lens dam 520 and the third lens dam 530 may be smaller than the first height H1 of the first lens dam 510. Accordingly, the first height H1 of the first lens dam 510 may be the largest, and the third height H3 of the third lens dam 530 may be the smallest. The second height H2 of the second lens dam 520 may be smaller than the first height H1 and greater than the third height H3, but is not limited thereto. As a result, the first head portion 511 of the first lens dam 510 may first prevent the insulating material having fluidity from overflowing over the second lens dam 520 or the third lens dam 530.

In an example, the third lens dam 530 may be disposed so as not to overlap the third encapsulation dam 430 disposed thereunder and in the second area A2 in the vertical direction. For example, in the plan view, the third lens dam 530 may be disposed outwardly of the third encapsulation dam 430 or at a position corresponding to or overlapping a position between the second pattern 265b2 of the second encapsulation dam 420 and the third encapsulation dam 430.

In another example, the third lens dam 530 may be disposed to overlap the third encapsulation dam 430 disposed thereunder and in the second area A2 in the vertical direction. In this case, the second lens dam 520 may be disposed at a position corresponding to or overlapping a space S between the first pattern 265b1 and the second pattern 265b2 of the second encapsulation dam 420. When the third lens dam 530 overlaps the third encapsulation dam 430 having the multi-layered structure in the vertical direction, the third height H3 of the third lens dam 530 may be relatively greater than the second height H2 of the second lens dam 520. For example, the first height H1 of the first lens dam 510 may be the largest, and the second height H2 of the second lens dam 520 may be the smallest. Then, when the polarizing layer 360 is attached thereto, a physical pressure applied onto the third lens dam 530 having the relatively larger height than that of the second lens dam 520 may increase. When the physical pressure is continuously increased, the damage may occur to the third lens dam 530. When the damage occurs to the third lens dam 530, the second lens dam 520 may function to supplement the third lens dam 530, thereby maintaining the state in which the polarizing layer 360 is attached thereto. This may prevent the occurrence of the lift off defect of the polarizing layer 360 in the product.

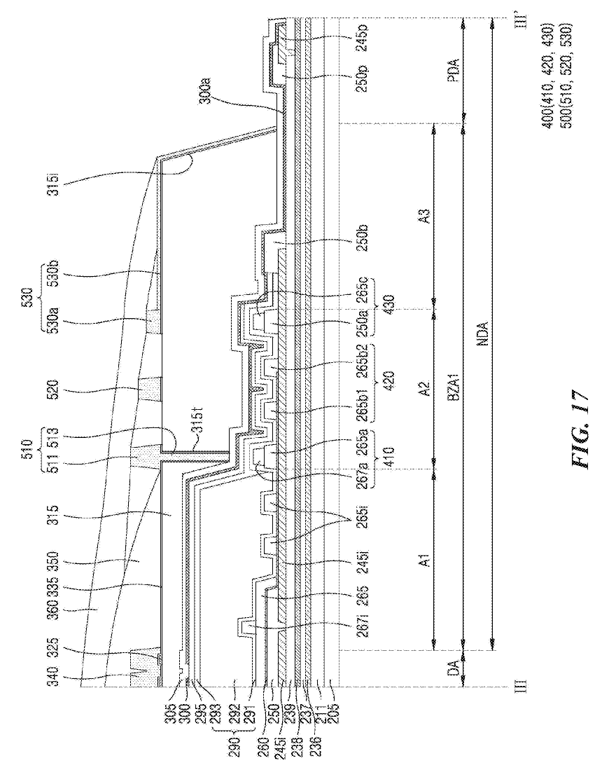

FIG. 17 is a diagram illustrating a display apparatus according to still yet another example implementation of the present disclosure. Since FIG. 17 includes the same components as those in FIG. 15 except for the lens dams, redundant descriptions thereof will be omitted or briefly set forth, and differences therebetween will be described. Like reference numerals may denote like elements.

Referring to FIG. 17, the plurality of lens dams 500 may be disposed on the passivation layer 335. The plurality of lens dams 500 may include the first lens dam 510 overlapping the trench 315t, the second lens dam 520, and the third lens dam 530. Each of the plurality of lens dams 500 may be made of the same material as that of the lens 340 of the display area DA and be formed in the same process as the process for forming the lens 340 of the display area DA, but is not limited thereto.

At least one of the plurality of lens dams 500 may be disposed in the second area A2 of the bezel area BZA1 and BZA2 in which the encapsulation dams 410, 420, and 430 are disposed. For example, the first lens dam 510 may be disposed to overlap the underlying first encapsulation dam 410 in the vertical direction. For example, as illustrated in FIG. 10, the first center line C1 of the first width 510w of the first head portion 511 of the first lens dam 510 may coincide with the second center line C2 of the second width 410w of the first encapsulation dam 410 positioned thereunder.

The lens dams 510, 520, and 530 may be constructed to have different heights. For example, the height of the first head portion 511 of the first lens dam 510 may be the largest. The height of each of the second lens dam 520 and the third lens dam 530 may be smaller than the height of the first head portion 511 of the first lens dam 510. For example, the height of the third lens dam 530 may be the smallest. The height of the second lens dam 520 may be smaller than the height of the first head portion 511 of the first lens dam 510 and greater than the height of the third lens dam 530, but is not limited thereto.

The height of each of the lens dams 510, 520, and 530 according to another example implementation of the present disclosure may be greater than the width in the direction from the lens to the side end of the substrate of the bottom surface thereof. The first lens dam 510, the second lens dam 520, and the third lens dam 530 may be arranged in a stepwise manner whose the vertical levels of the upper surfaces thereof are sequentially lowered as the first lens dam 510, the second lens dam 520, and the third lens dam 530 are sequentially arranged in a direction toward the side end of the substrate 205. The second lens dam 520 may be disposed between the first lens dam 510 and the third lens dam 530.

The polarizing layer 360 may continuously extend across the first area A1 to the third area A3 and be attached to the first area A1 to the third area A3. The polarizing layer 360 may be in contact with the lens dams 520, 520, and 530 arranged in the stepwise manner. Accordingly, the vertical level of the upper surface of the polarizing layer 360 may be gradually lowered as the polarizing layer 360 extends toward the third area A3. As a result, the polarizing layer 360 may be closely attached to the second pattern portion 530b of the third lens dam 530 disposed in the edge of the third area A3 and may not lift off.

The display apparatus according to various aspects and implementations of the present disclosure may be described as follows.

One aspect of the present disclosure provides a display apparatus comprising: a substrate including a display area and a non-display area disposed outside the display area; a bezel area located in the non-display area and including a first area in which a plurality of first structures are disposed; an encapsulation portion disposed on the plurality of first structures; a touch sensing unit disposed on the encapsulation portion and including a touch sensor and a touch insulating layer; and a first trench penetrating the touch insulating layer in the first area.

In accordance with some implementations, the display apparatus further comprise: a lens disposed on the touch sensing unit; a lens protection layer disposed on the lens; and a plurality of second structures disposed to be spaced apart from the lens, wherein one of the plurality of second structures overlaps the first trench.

In accordance with some implementations, the plurality of second structures are disposed in the first area in which the plurality of first structures are disposed.

In accordance with some implementations, the refractive index of the lens protection layer is lower than the refractive index of the lens, and the lens protection layer includes an insulating material having fluidity.

In accordance with some implementations, the one second structure includes a first pillar portion and a first head portion: the first pillar portion filling the first trench; and the first head portion disposed on the first pillar portion.

In accordance with some implementations, the one second structure overlaps one first structure among the plurality of first structures in the vertical direction, a bottom surface of the one second structure has a first width, and a bottom surface of the one first structure has a second width, a first center line passing through a center of the first width of the second structure and a second center line passing through a center of the second width of the one first structure coincide with each other.

In accordance with some implementations, the bezel area further includes a second area between the first area and the display area, and a third area between the first area and an end portion of the substrate, the plurality of first structures include: a first encapsulation dam disposed in the first area and in a boundary area between the first area and the second area; a third encapsulation dam disposed in the first area and in a boundary area between the first area and the third area; and a second encapsulation dam disposed in the first area and between the first encapsulation dam and the third encapsulation dam, wherein the first encapsulation dam is disposed to overlap one of the plurality of second structures in the vertical direction.

In accordance with some implementations, the first encapsulation dam and the third encapsulation dam have a structure in which a plurality of layers are stacked in a vertical direction, and the second encapsulation dam includes a plurality of patterns spaced apart from each other in a horizontal direction.

In accordance with some implementations, the plurality of second structures includes: a first lens dam disposed in the first area to overlap one of the plurality of first structures in a vertical direction; a second lens dam disposed outwardly of the first lens dam; and a third lens dam disposed outwardly of the second lens dam, wherein the first lens dam is disposed to overlap the first encapsulation dam.

In accordance with some implementations, the second structure includes a material having a density higher than a density of a material of the touch insulating layer.

In accordance with some implementations, each of the first lens dam, the second lens dam, and the third lens dam each have a first width and a height smaller than the first width.

In accordance with some implementations, an upper surface of the first lens dam is positioned at a vertical level higher than a vertical level of an upper surface of the second lens dam or an upper surface of the third lens dam.

In accordance with some implementations, the third lens dam includes a first pattern portion and a second pattern portion extending from one side surface of the first pattern portion outwardly.

In accordance with some implementations, the first lens dam includes a first pillar portion and a first head portion: wherein the first pillar portion filling the first trench, wherein the first head portion disposed on the first pillar portion, and wherein each of the width and the height of each of the second lens dam and the third lens dam is equal to each of the width and the height of the first head portion of the first lens dam.

In accordance with some implementations, wherein the first trench has a pillar shape extending through the touch insulating layer and extending in a line coinciding with the first center line of the second structure and the second center line of the first structure.

In accordance with some implementations, a second trench extends through the touch insulating layer and overlaps the second lens dam, and a third trench extends through the touch insulating layer, is spaced apart from the second trench, and overlaps the third lens dam.

In accordance with some implementations, the second lens dam includes a second pillar portion and a second head portion, and the third lens dam includes a third pillar portion and a third head portion, wherein the second pillar portion filling the second trench, wherein the second head portion disposed on the second pillar portion, wherein the third pillar portion filling the third trench, and wherein the third head portion disposed on the third pillar portion.

In accordance with some implementations, the first trench includes a first trench pattern and a second trench pattern disposed to be spaced apart from each other at both side edge portions of the first head portion, wherein the first pillar portion filling the first trench pattern includes a first sub-pillar portion and a second sub-pillar portion.

In accordance with some implementations, the plurality of second structures have a line shape continuously disposed along the display area, and the first trench has the same shape as the second structures.

In accordance with some implementations, a passivation layer made of the inorganic insulating material is formed in the first trench.

In accordance with some implementations, the lens includes a material having a density higher than a density of a material of the touch insulating layer.

A display apparatus according to another example implementation of the present disclosure includes: a substrate including a display area and a non-display area disposed outside the display area; a bezel area located in the non-display area and including a first area in which a plurality of encapsulation dams are disposed; an organic insulating layer disposed over the plurality of encapsulation dams; a lens disposed on the organic insulating layer; one or more trenches penetrating the organic insulating layer in the first area; and a lens dam filling the one or more trenches.

Although implementations of the present disclosure have been described with reference to the accompanying drawings, the present disclosure is not limited to the above implementations, but may be implemented in various different forms. A person skilled in the art may appreciate that the present disclosure may be practiced in other concrete forms without changing the technical spirit or essential characteristics of the present disclosure. Therefore, it should be appreciated that the implementations as described above are not restrictive but illustrative in all respects.

What is claimed is:

1. A display apparatus comprising:
a substrate including a display area and a non-display area disposed outside the display area;
a bezel area located in the non-display area and including a first area in which a plurality of first structures are disposed;
an encapsulation portion disposed on the plurality of first structures;
a touch sensing unit disposed on the encapsulation portion and including a touch sensor and a touch insulating layer; and
a first trench penetrating the touch insulating layer in the first area of the bezel area.

2. The display apparatus of claim 1, further comprising:
a lens disposed on the touch sensing unit;
a lens protection layer disposed on the lens; and
a plurality of second structures disposed to be spaced apart from the lens,
wherein one second structure of the plurality of second structures overlaps the first trench, and
wherein the plurality of second structures are disposed in the first area in which the plurality of first structures are disposed.

3. The display apparatus of claim 2, wherein a refractive index of the lens protection layer is lower than a refractive index of the lens, and
wherein the lens protection layer includes an insulating material having fluidity.

4. The display apparatus of claim 2, wherein the one second structure includes a first pillar portion and a first head portion:
wherein the first pillar portion fills the first trench; and
wherein the first head portion is disposed on the first pillar portion.

5. The display apparatus of claim 2, wherein the one second structure overlaps one first structure among the plurality of first structures in a vertical direction,
wherein a bottom surface of the one second structure has a first width, and a bottom surface of the one first structure has a second width,
wherein a first center line passing through a center of the first width of the one second structure along the vertical direction coincides with a second center line passing through a center of the second width of the one first structure in the vertical direction.

6. The display apparatus of claim 2,
wherein the bezel area further includes a second area between the first area and the display area, and a third area between the first area and an end portion of the substrate,
wherein the plurality of first structures include:
a first encapsulation dam disposed in the first area and in a boundary area between the first area and the second area;
a third encapsulation dam disposed in the first area and in a boundary area between the first area and the third area; and
a second encapsulation dam disposed in the first area and between the first encapsulation dam and the third encapsulation dam,
wherein the first encapsulation dam is disposed to overlap one of the plurality of second structures in a vertical direction.

7. The display apparatus of claim 6, wherein
the first encapsulation dam and the third encapsulation dam each have a structure in which a plurality of layers are stacked in a vertical direction, and
the second encapsulation dam includes a plurality of patterns spaced apart from each other in a horizontal direction.

8. The display apparatus of claim 6, wherein the plurality of second structures includes:
a first lens dam disposed in the first area and overlapping one first structure of the plurality of first structures in a vertical direction;
a second lens dam disposed further in an outward direction than the first lens dam; and
a third lens dam disposed further in the outward direction than the second lens dam,
wherein the first lens dam is disposed to overlap the first encapsulation dam.

9. The display apparatus of claim 6, wherein the one second structure includes a material having a density higher than a density of a material of the touch insulating layer.

10. The display apparatus of claim 8, wherein each of the first lens dam, the second lens dam, and the third lens dam has a first width and a height smaller than the first width.

11. The display apparatus of claim 8, wherein an upper surface of the first lens dam is positioned at a first vertical level that is higher than a second vertical level of an upper surface of the second lens dam or a third vertical level of an upper surface of the third lens dam.

12. The display apparatus of claim 8, wherein the third lens dam includes a first pattern portion and a second pattern portion extending from one side surface of the first pattern portion in the outward direction.

13. The display apparatus of claim 8, wherein the first lens dam includes a first pillar portion and a first head portion:
wherein the first pillar portion fills the first trench,
wherein the first head portion is disposed on the first pillar portion, and
wherein a width and a height of each of the second lens dam and the third lens dam are equal to a width and a height of the first head portion of the first lens dam.

14. The display apparatus of claim 5, wherein the first trench includes a pillar shape extending through the touch insulating layer and extending along a line coinciding with the first center line of the second structure and the second center line of the first structure.

15. The display apparatus of claim 8, further comprising:
a second trench extending through the touch insulating layer and overlapping the second lens dam; and
a third trench extending through the touch insulating layer, spaced apart from the second trench and overlapping the third lens dam.

16. The display apparatus of claim 15, wherein:
the second lens dam includes a second pillar portion and a second head portion,
the third lens dam includes a third pillar portion and a third head portion,
the second pillar portion fills the second trench,
the second head portion is disposed on the second pillar portion,
the third pillar portion fills the third trench, and
the third head portion is disposed on the third pillar portion.

17. The display apparatus of claim 4, wherein the first trench includes (i) a first trench pattern at a first side edge portion of the first head portion and (ii) a second trench pattern at a second side edge portion of the first head portion and spaced apart from the first trench pattern, and
wherein the first pillar portion filling the first trench pattern includes a first sub-pillar portion and a second sub-pillar portion.

18. The display apparatus of claim 2, wherein each of the plurality of second structures has a line shape continuously disposed along the display area, and
wherein the first trench has a same shape as each of the plurality of second structures.

19. The display apparatus of claim 1, wherein a passivation layer comprising an inorganic insulating material is disposed in the first trench.

20. The display apparatus of claim 2, wherein the lens includes a material having a density higher than a density of a material of the touch insulating layer.

21. A display apparatus comprising:
a substrate including a display area and a non-display area disposed outside the display area;
a bezel area located in the non-display area and including a first area in which a plurality of encapsulation dams are disposed;
an organic insulating layer disposed over the plurality of encapsulation dams;
a lens disposed on the organic insulating layer;
one or more trenches penetrating the organic insulating layer in the first area of the bezel area; and
a lens dam that fills the one or more trenches.
